(19) United States
(12) Patent Application Publication
(10) Pub. No.: US 2025/0185444 A1
(43) Pub. Date: Jun. 5, 2025

(54) TRANSFERRABLE ELECTRODE FOR PRINTED ELECTRONICS

(71) Applicant: COMMONWEALTH SCIENTIFIC AND INDUSTRIAL RESEARCH ORGANISATION, Australian Capital Territory (AU)

(72) Inventors: Luke SUTHERLAND, Victoria (AU); Hasitha WEERASINGHE, Victoria (AU); Doojin VAK, Victoria (AU); Mei GAO, Victoria (AU)

(21) Appl. No.: 18/844,822

(22) PCT Filed: Mar. 10, 2023
(86) PCT No.: PCT/AU2023/050170

§ 371 Date: Sep. 6, 2024

(30) Foreign Application Priority Data
Mar. 10, 2022 (AU) 2022900582

(51) Int. Cl. H10K 30/81; H10K 30/50; H10K 71/40; H10K 71/60; H10K 77/10

(52) U.S. Cl. CPC H10K 30/81; H10K 30/50; H10K 71/40; H10K 71/60; H10K 77/111

(57) ABSTRACT

A transferrable electrode arrangement comprising: a flexible release substrate having a release surface; and a transferrable electrode comprising at least one conductive layer located over the release surface of the release substrate comprising a solution-processed conductive layer, wherein the at least one conductive layer includes an interfacing conductive layer that interfaces with a receiving surface, and comprises a carbonaceous conductive layer or an organic conductive layer, and wherein the transferrable electrode is releasably attached to the release surface of the release substrate.

### PRIORITY CROSS-REFERENCE

The present application claims priority from Australian Provisional Patent Application No. 2022900582 filed on 10 Mar. 2022, the contents of which should be understood to be incorporated into the present specification by this reference.

### TECHNICAL FIELD

The present invention relates to a transferrable electrode arrangement that can be used in printed electronics, and more particularly in flexible electronics. The invention is particularly applicable for forming an electrode that can be applied/transferred onto a flexible electronics substrate such as a printed optoelectronic device to form the electrode thereon and it will be convenient to hereinafter disclose the invention in relation to that exemplary application. However, it is to be appreciated that the invention is not limited to that application and could be used in a number of printed electronic applications including electronic sensors, light-emitting devices, or the like.

### BACKGROUND OF THE INVENTION

The following discussion of the background to the invention is intended to facilitate an understanding of the invention. However, it should be appreciated that the discussion is not an acknowledgement or admission that any of the material referred to was published, known or part of the common general knowledge as at the priority date of the application.

Printed electronics, such as thin-film photovoltaic devices, are traditionally fabricated with each layer progressively printed over a preceding layer to form the final multilayered product. Whilst this allows each layer to have a tailored configuration and composition, the composition and particularly the solvents used in successive layers must be carefully selected to minimise, and more preferably prevent damage to the underlying layer. Nevertheless, some layers, for example, the top electrode layer, can still have components and treatment regimens that can be detrimental to the underlying layers.

The top electrode of a thin film photovoltaic device is conventionally applied using expensive/low-throughput vacuum evaporation deposition of a metal, such as silver or gold, onto the application layer of an electronic carrier substrate having selected underlying electronic layers configured for receipt of the transferrable electrode. The process is conducted in high vacuum chambers and therefore can be very costly and can be difficult to upscale for high-volume manufacturing.

Alternatively, the electrode is solution printed/coated directly onto the electronic carrier substrate and then undergoes a heat treatment (annealing) process to dry the electrode layer. The heat treatment process can cause partial damage to other layers of the device through degradation of some underlying layers of the device. This solution printing/coating method can also allow undesirable solvents in the wet film to seep into one or more underlying layers of the electronic carrier substrate and potentially cause damage to one or more of these layers or the interfaces between the layers. Therefore, the choice of conductive pastes is restricted, and the performance of electrodes is compromised for chemical compatibility.

It would therefore be desirable to provide a new or improved method of forming an electrode for a flexible electronic device, such as a thin film photovoltaic device.

### SUMMARY OF THE INVENTION

The present invention relates to a transferrable electrode, an arrangement associated with the transferrable electrode, flexible electronic devices such as optoelectronic devices that incorporate that transferrable electrode, methods of forming a transferrable electrode and methods of forming flexible electronic devices that incorporate that transferrable electrode.

A first aspect of the present invention provides a transferrable electrode arrangement comprising:
a flexible release substrate which includes a release surface; and
a transferrable electrode comprising at least one conductive layer located over the release surface of the release substrate comprising a solution-processed conductive layer,
wherein the at least one conductive layer includes an interfacing conductive layer that interfaces with a receiving surface, and comprises a carbonaceous conductive layer or an organic conductive layer,
and wherein the transferrable electrode is releasably attached to the release surface of the release substrate.

The first aspect of the present invention therefore relates to an arrangement that includes a transferrable electrode, preferably a thin film electrode, where that transferrable electrode is located on a release substrate that has a release surface, for example a non-stick surface or other releasably attachable configured surface (as discussed below). The release surface provides a surface on which the transferrable electrode is releasably stuck, affixed or otherwise attached. The release substrate can be separated from the transferrable electrode once the transferrable electrode has interfaced with and been fixed to, attaches to, or is otherwise adhered to the receiving surface.

The electrode includes at least one conductive layer that is transferable to an in-use location, for example, an electronic carrier substrate having selected underlying electronic layers configured for receipt of the transferrable electrode on a receiving surface thereon. The conductive layer layup includes at least one interfacing conductive layer which is configured to interface with a receiving surface, for example the receiving surface of an electronic carrier substrate as described later in this specification. One example exemplified in the present application is the formation of a flexible optoelectronic device using the transferrable electrode as the outer electrode layer of the lay-up of the optoelectronic device.

It should be appreciated that the interfacing conductive layer is preferably configured with a composition and configuration that allows the releasable substrate to interface with that appropriate receiving surface. By interface, it is meant, abut, engage with and/or substantially adhere with the receiving surface, for example a receiving surface of an electronic carrier substrate. The interface layer is therefore typically the outermost layer of the conductive layer layup, being the furthest layer away from the release substrate.

The use of the electrode layer that is formed separately from the other layers of the electronic device allows the transferable electrode to be fabricated and heat treated separately to the layup of the intended electronic carrier substrate, thereby isolating the electronic carrier substrate from any heat treatment (annealing) and solvent leaching issues associated with the composition and formation of the transferable electrode layer that could otherwise cause some degradation of some underlying layers of the optoelectronic device if formed insitu on the electronic carrier substrate. The transferable electrode can comprise a flexible electrode—for example, a flexible cathode or a flexible anode depending on the layup of the electronic carrier substrate.

It should be understood that the solution-processed conductive layer can comprise any conductive layer formed from a fabrication method in which the materials forming the layer are deposited while such materials are in solution (otherwise known as a “wet” processing method). This is in contrast to “dry” processing methods wherein such materials are deposited while in a gas or vapor phase. A solution-processed layer typically comprises the material, in this case, a conductive material, a binder, typically an organic binder deposited into that layer. The wet solution used to form that solution-processed conductive layer typically comprises the conductive material, a binder, mixed together within a solvent. Any suitable binder can be used. Examples of suitable binders include organic binders such as one or more of ethyl cellulose, butyl cellulose, nitrocellulose, hydroxylcellulose, cellulose acetate butyrate, alkyd resins, epoxy resin, phenolic resins, acrylic resin, butyl carbitol, butadiene-styrene rubber, polyvinylpyrrolidone, polyacrylamide, cellulose derivatives, triethyl group hexyl phosphoric acid and lauryl sodium sulfate.

It should be understood that as used herein, the term “conductive layer” means a thin film with sufficient electrical conductivity to transport a charge or charges, for example photo-generated charges, through the layer. A conductive layer may be an electrical conductor or a semiconductor. A “conductive layer” can have multiple functions including charge selectivity.

The conductive layer can have any composition suitable for use in a solution printed flexible electronic device, for example, a flexible optoelectronic device. In embodiments, the at least one conductive layer comprises at least one further conductive layer selected from: a metallic-based conductive layer; a carbonaceous conductive layer; an organic conductive layer; or a combination thereof. In embodiments, the at least one further conductive layer comprises a metallic-based conductive layer.

The transferrable electrode can be formed from a single conductive layer composition, or two or more conductive layer compositions. In embodiments, the transferrable electrode comprises at least one metallic-based conductive layer located over the release surface of the release substrate. In some embodiments, the transferrable electrode comprises at least a carbonaceous conductive layer located over the release surface of the release substrate. In some embodiments, the transferrable electrode comprises at least one organic conductive layer located over the release surface of the release substrate. In other embodiments, the transferrable electrode comprises at least two conductive layers comprising:
at least one metallic-based conductive layer located over the release surface of the release substrate; and
the interfacing conductive layer located over the metallic-based conductive layer.

In embodiments, the transferrable electrode comprises a single-layered electrode with only one conductive layer (carbonaceous or organic conductive layer). In other embodiments, the transferrable electrode comprises a bi-layered electrode, preferably including both a metal-based conductive layer and the interfacing conductive layer.

In this electrode compositional lay-up, the transferrable electrode can include one or more metallic-based conductive layers. Similarly, the transferrable electrode can include one or more interfacing conductive layers comprising the carbonaceous conductive layer or the organic conductive layer. The layup of the transferrable electrode can in embodiments have a first layer or layered section of the metallic-based conductive material, followed by a second layer or layered section of the interfacing conductive layer. However, it should be appreciated that the layers could be applied in a consecutive manner to form a metallic-based conductive layer followed by the interfacing conductive layer (carbonaceous conductive layer or organic conductive layer) layered structure if desired. The interfacing conductive layer is the final, outer layer of the transferrable electrode—located furthest from the release substrate in the layup, to provide a surface that is positioned to interface with a receiving surface.

Barrier encapsulation is useful for protecting flexible electronic devices from degrading due to the interaction of the functional layers of the device with ambient atmosphere (i.e. moisture and oxygen in that ambient atmosphere). In some embodiments, the transferrable electrode further comprises at least one barrier film layer located between the release substrate and the at least one conductive layer. A barrier film layer is thus located between the conductive layer and the release substrate, so that when the release substrate is removed (see embodiments of the present invention described below), the barrier film forms a protective layer over that conductive layer and the transferrable electrode. The barrier film can comprise any suitable material. In embodiments, the barrier film can comprise a single thin-film barrier layer, or a multilayer thin-film barrier structure. This could be any suitable material that provides barrier properties including polymeric barrier materials such as ethylene-vinyl acetate (EVA), polydimethylsiloxane (PDMS), poly(1,3,5-trimethyl-1,3,5-trivinylcyclotrisiloxane) (pV3D3), or the like, or organic-inorganic nanocomposites such as silica-based materials including as perhydropolysilazane (PHPS), or metallic oxide barrier layers such as aluminium oxide, silicon oxide, silicon nitride, titanium dioxide, tin oxide, or the like. Multilayer barrier structures could comprise a stack of alternating organic or inorganic layers or consecutive layers of organic or inorganic barrier materials such as those mentioned. It should be appreciated that the barrier film is preferably a very thin film which is too thin to handle. The barrier film has mechanical and physical properties which make it too thin to be a stand-alone film.

The conductive layer can have any suitable conductive composition:

Suitable metallic-based conductive layer layers include conductive composition based on Au, Ag, Al, Mg, Cu or suitable alloys thereof or the like. In embodiments, the at least one metallic-based conductive layer comprises an Ag, Al, Cu or Au based layer, preferably an Ag, Al or Cu based layer.

The at least one organic conductive layer preferably comprises a charge transport layer, preferably a PEDOT-based conductive layer. Suitable PEDOT-based conductive layers include PEDOT or PEDOT containing compositions such as Poly(3,4-ethylenedioxythiophene):poly(styrene sulfonate) (PEDOT:PSS).

It should be understood that a carbonaceous conductive layer comprises a layer that contains or comprises a composition that is composed of and/or is rich in carbon or a carbon based material. Suitable carbonaceous conductive layers include compositions including carbon, graphite/carbon black, carbon nanotubes (CNTs), vapour-grown carbon fibers, graphene, or the like. The at least one carbonaceous conductive layer is preferably formed using a carbon-based/carbonaceous paste, that typically comprises a conductive carbonaceous filler, a binder material and an organic solvent. In embodiments, the conductive carbonaceous filler is selected from graphite, carbon black, carbon nanotubes, vapour grown carbon fibres, graphene, or a combination thereof. In embodiments, the binder material is selected from ethyl cellulose, butyl cellulose, nitrocellulose, hydroxylcellulose, cellulose acetate butyrate, alkyd resins, epoxy resin, butadiene-styrene rubber, phenolic resins, acrylic resin, butyl carbitol, butadiene-styrene rubber, polyvinylpyrrolidone, polyacrylamide, cellulose derivatives, triethyl group hexyl phosphoric acid and lauryl sodium sulfate, cellulose-based polymers, or a combination thereof. In embodiments, the organic solvent is selected from terpineol, dibutyl phthalate, butyl carbitol, dibutyl carbitol, turpentine oil, butyl glycol ether, butyl carbitol acetate, ethylene glycol ether acetate, tributyl citrate and tributyl phosphate, propylene glycol methyl ether acetatetoluene, diethylene glycol butyl ether, propanol, benzyl alcohol, isopropyl alcohol, ethanol, methanol, dimethylformamide, dimethylsulfoxide, chloroform, diethylene glycol derivatives, toluene, xylene isopropanol, ethyl acetate, water, chlorobenzene, or a combination thereof. Examples of commercially available carbon-based/carbonaceous paste that have this type of composition include: Dycotec DM-CAP-4701-S and Dycotec DM-CAP-4311-S from Dycotec Materials Ltd, United Kingdom; and Jelcon CH-8 from JUJO Chemical Co Ltd, Japan. In embodiments, the carbonaceous conductive layer comprises a porous, preferably macroporous carbonaceous conductive film.

In some embodiments, the transferrable electrode comprises a metallic-based conductive layer located over the release surface of the release substrate, and a carbonaceous conductive layer located over the metallic-based conductive layer.

In some embodiments, the transferrable electrode comprises a metallic-based conductive layer located over the release surface of the release substrate, and an organic conductive layer, preferably a PEDOT-based conductive layer, located over the metallic-based conductive layer. The organic conductive layer is preferably a charge transport layer.

The transferable electrode of the present invention is preferably a thin film electrode. The thin-film electrode is typically so thin that it is not self-supporting (i.e. it is physically unstable) and thus requires the release substrate in order to be transported and manipulated. In embodiments, the at least one conductive layer has a dry layer thickness from 1 μm to 100 μm, preferably from 10 to 80 μm, more preferably from 20 to 60 μm, and yet more preferably about 40 μm. In embodiments, the interfacing conductive layer (and in particular a carbonaceous conductive based interfacing conductive layer) has a dry layer thickness of between 10 to 50 μm, preferably from 15 to 40 μm, and more preferably from 30 to 40 μm.

The release substrate can comprise any suitable material. In embodiments, the release substrate comprises a flexible polymer or a flexible film. Examples include a polymer film, such as a polyethylene terephthalate (PET) film, polyethylene naphthalate (PEN), polypropylene (PP), ethylene tetrafluoroethylene (ETFE) or could comprise a paper-based or metal-based substrate such as paper or aluminium foil or the like.

The transferrable electrode is releasably attached to the release surface of the release substrate. In this sense, the release surface provides a surface on which the transferrable electrode is releasably stuck, affixed or otherwise attached thereon. It should be understood that releasably attached means that the transferrable electrode is stuck, attached or otherwise affixed to the release substrate in a way that also allows the transferrable electrode to be subsequently separated from the transferrable electrode using a selected action, for example delamination/force, heat, radiation, chemical reaction or the like. The release substrate is typically separated from the transferrable electrode once the transferrable electrode has interfaced with and been fixed (or otherwise adhered to) the receiving surface. The release surface on the release substrate can take a number of forms which allow the release substrate to be detached or otherwise removed from the transferable electrode.

In some embodiments, the release surface comprises a non-stick surface, preferably a non-stick coating or a low adhesion coating. The release substrate is preferably coated with a non-stick coating. It should be appreciated that a non-stick surface and/or coating is surface engineered to reduce the ability of other materials to stick to it. In this sense, the coating has a composition that provides a low adhesion surface. The non-stick surface may be provided by a low surface energy polymer. The non-stick coating may comprise a low surface energy polymer, for example selected from the group consisting of a fluorinated polymer and a silicone polymer. The release surface is preferably selected from the group consisting of a fluorinated polymer and a silicone polymer. Examples include polytetrafluoroethylene (PTFE), or silicone derivatives such as siloxane. In this embodiment, the release substrate is separable from the transferable electrode by delaminating/removing the transferable electrode from the non-stick surface.

In other embodiments, the release surface comprises an activatable adhesive which can be activated to separate the transferrable electrode from the release substrate. Examples of suitable activatable adhesives include a heat-activatable adhesive polymer, preferably comprising a thermoplastic polymer selected from the group consisting of an ethylene-vinyl acetate (EVA) copolymer, a polyethylene, a polyethyleneoxide (PEO) and a polystyrene (PS). In this embodiment, the release substrate is separable from the transferable electrode when the activatable adhesive is activated, for example using heat for a heat activatable adhesive. Here, the activatable adhesive is heat-activatable at a temperature sufficient to release/separate the release substrate from the transferrable electrode.

It should be appreciated that as used herein, an “activatable” layer, adhesive or adhesive polymer is adapted to be functionally activated, for adhesion or debonding as required, by an external stimulus such as heat, radiation (e.g. actinic light) or chemical treatment.

In other embodiments, the release surface comprises a low-cohesion sacrificial layer interposed between the flexible release substrate and the transferrable electrode, wherein the low-cohesion sacrificial layer has intrinsically low cohesion or has low cohesion when activated such that the flexible release substrate is separable from the transferrable electrode by breaking the low-cohesion sacrificial layer. The low-cohesion sacrificial layer can comprise at least one of: a low-cohesion organic non-polymeric solid; or an activatable adhesive which can be activated by heat or radiation to breaking the low-cohesion sacrificial layer and thereby separate the transferrable electrode from the release substrate. In this embodiment, the activatable adhesive can be a thermoplastic polymer, for example selected from the group consisting of an ethylene-vinyl acetate (EVA) copolymer, a polyethylene, a polyethyleneoxide (PEO) and a polystyrene (PS), or a light-depolymerizable polymeric composition, preferably selected from the group consisting of poly(phthalaldehyde) (PPHA) combined with photo acid generator (PAG), poly(acetal) s combined with PAG and polylactide (PLA) combined with TiO₂. In some embodiments, the low-cohesion sacrificial layer can be conductive, thus any residue does not hinder the conductive function of the transferrable electrode. The low-cohesion sacrificial layer can have any suitable thickness. In some embodiments, the low-cohesion sacrificial layer has a thickness of less than 100 nm, preferably less than 20 nm. In this embodiment, the release substrate is separable from the transferable electrode by (i) activating the activatable adhesive by heat or radiation and (ii) breaking the low-cohesion sacrificial layer.

A second aspect of the present invention provides an optoelectronic device that incorporates the transferrable electrode arrangement of the first aspect of the present invention. The second aspect of the present invention provides an optoelectronic device comprising:
a flexible substrate coated with a transparent conductive oxide coating;
a first charge transport layer located over the flexible substrate;
at least one photoactive layer located over the first charge transport layer; and
the transferrable electrode arrangement according to the first aspect of the present invention located over the photoactive layer, with the interfacing conductive layer located over the photoactive layer, preferably interfacing with (attached/adhered to and in engagement with) the photoactive layer.

In this second aspect, the optoelectronic device is a multilayered optoelectronic device formed on a flexible substrate which is capped with the transferrable electrode arrangement of the first aspect of the present invention, with the interfacing conductive layer of the transferrable electrode interfacing with the at least one photoactive layer within the optoelectronic device.

In some embodiments, the transferrable electrode arrangement is located in direct engagement with the photoactive layer of the optoelectronic device. In these embodiments, the transferrable electrode preferably comprises a metallic-based conductive layer located over the release surface of the release substrate, and the interfacing conductive layer comprises an organic conductive layer, preferably a charge transport layer, and more preferably a PEDOT based conductive layer, located over the metallic-based conductive layer.

In other embodiments, the transferrable electrode arrangement is in engagement with a further layer that is located over the photoactive layer. In this regard, the multi-layered composition of the optoelectronic device can include the above defined layers along with one or more additional layers. For example, in some embodiments, the optoelectronic device further comprises a second charge transport layer located over the flexible substrate located between the at least one photoactive layer and the transferrable electrode. It should be appreciated that other suitable layers could also be included in the layup depending on the desired configuration of the optoelectronic device. Where the transferrable electrode arrangement is in engagement with (located over) the second charge transport layer, the transferrable electrode preferably comprises a metallic-based conductive layer located over the release surface of the release substrate, and the interfacing conductive layer comprises a carbonaceous conductive layer located over the metallic-based conductive layer. In this embodiment, the interfacing conductive layer of the transferrable electrode interfaces with (is in direct engagement with and is attached/adhered to) the second charge transport layer within the optoelectronic device. In embodiments, the carbonaceous conductive layer comprises a porous, preferably macroporous carbonaceous conductive film.

The first charge transport layer and second charge transport layer can have any suitable composition. In embodiments, at least one of the first charge transport layers or the second charge transport layer comprises at least one hole transporting layer, at least one electron transport layer, or at least one photovoltaic cell active layer. These layers can have a variety of compositions, depending on the desired optoelectronic device configuration:
Suitable hole transporting layers include a transparent conducting polymer such as at least one of 2,2′,7,7′-tetrakis-(N,N-di-4-methoxyphenylamino)-9,9′-spirobifluorene (Spiro-OMeTAD), poly[(2,5-bis(2-hexyldecyloxy)phenylene)-alt-(5,6-difluoro-4,7-di(thiophen-2-yl)benzo[c][1,2,5]-thiadiazole)](PPDT2FBT), Poly(3,4-ethylenedioxythiophene) (PEDOT), poly(3,4-ethylenedioxythiophene and polystyrene sulfonate mixture (PEDOT:PSS), poly(4,4-dioctylcyclopentadithiophene); P3HT, doped P3HT (Poly(3-hexylthiophene-2,5-diyl)), poly(triarylamine) (PTAA), poly[N-9″-heptadecanyl-2,7-carbazole-alt-5,5-(4′,7′-di-2-thienyl-2′,1′,3′-benzothiadiazole)] (PCDTBT), poly[2,6-(4,4-bis-(2-ethylhexyl)-4H-cyclopenta[2,1-b; 3,4-b′]dithiophene)-alt-4,7 (2,1,3-benzothiadiazole)] (PCPDTBT), poly(N-alkyldiketopyrrolopyrroledithienylthieno[3,2-b] thiophene) (DPP-DTT), indene-C60 bisadduct (ICBA), MoOs or the like;
Suitable electron transporting layers include transparent conductive oxides such as at least one of tin oxide, nickel oxide, zinc oxide, titanium dioxide, tungsten trioxide or the like, or transparent conductive polymers such as [6,6]-Phenyl-C61-butyric acid methyl ester (PC60BM), [6,6]-Phenyl-C70-butyric acid methyl ester (PC70BM), polyethylenimine ethoxylated (PEIE) or the like, or pristine fullerene mixtures such as C60 or C70, or the like; and
Suitable photovoltaic cell active layer includes: organic photovoltaic active layers such as any fullerene and non-fullerene polymeric electron-acceptor materials such as phenyl-C61-butyric acid methyl ester (PCBM) and any polymeric electron-donor materials such as poly(3-hexylthiophene) (P3HT); or perovskite photoactive layers.

In some embodiments, the transferable electrode arrangement comprises a metallic-based conductive layer located over the release surface of the release substrate, and a organic conductive layer that is located in direct engagement (interfaces with and is attached/adhered to) with the photoactive layer of the optoelectronic device. That photoactive layer is preferably comprised of a mixture of polymeric electron donors (i.e. P3HT) and polymeric electron acceptors (i.e. PCBM) or a perovskite photoactive layer.

In some embodiments, the at least one hole transporting layer comprises an organic or inorganic conductor or semiconductor. In some embodiments, the at least one electron transporting layer comprises an organic or inorganic conductor or semiconductor.

In exemplary embodiments, at least one of the first charge transport layers or the second charge transport layers is selected from at least one of: Spiro-OMeTAD, PPDT2FBT, or Phenyl-C61-butyric acid methyl ester (PCBM)/polyethylenimine ethoxylated (PEIE).

It should be noted that the composition of the first charge transport layer or the second charge transport layer may include one or more additives.

The photoactive layer can include a suitable photoactive composition. One exemplary photoactive layer comprises at least one perovskite layer. It should be appreciated that a photoactive perovskite layer comprises a light-absorbing perovskite semiconductor that consists essentially of crystallites of the perovskite. As will be discussed later in the specification, the term “perovskite”, as used herein, refers to (a) a material with a three-dimensional crystal structure related to that of CaTiO₃ or (b) a material comprising a layer of material, wherein the layer has a structure related to that of CaTiO₃. A perovskite material can be represented by the formula [A][M][X]₃, wherein [A] is at least one cation, [M] is at least one cation and [X] is at least one anion.

In embodiments, the transparent conductive oxide (TCO) coating is selected from at least one of tin-doped indium oxide (ITO), fluoride-doped tin oxide (FTO), doped zinc oxide such as aluminium doped zinc oxide (AZO), or indium doped cadmium-oxide.

The flexible substrate preferably comprises a polymer, preferably a polymer film, and more preferably a polyethylene terephthalate (PET), a polyethylene naphthalate (PEN), or a ethylene tetrafluoroethylene (ETFE) film, and more preferably a polyethylene terephthalate film.

For practical use, the release substrate of the transferable electrode arrangement is sacrificial and is therefore preferably removed. The optoelectronic device of the second embodiments therefore can have the release substrate at least partially separated from covering the transferrable electrode. In embodiments, the release substrate is partially separated from covering the at least one metallic-based conductive layer. Where the transferrable electrode includes a barrier layer, the release substrate is partially separated from covering the barrier film layer. More preferably, the optoelectronic device according to the second aspect has the release substrate substantially separated from covering the transferrable electrode. In embodiments, the release substrate is substantially separated from covering the at least one metallic-based conductive layer. Where the transferrable electrode includes a barrier layer, the release substrate is substantially separated from covering the barrier film layer.

A third aspect of the present invention provides a method of forming a transferrable electrode for a flexible electronic device, comprising:
providing a flexible release substrate that includes a release surface;
applying at least one layer of a conductive medium over the release surface of the release substrate, the conductive medium comprising a flowable mixture of a solvent with a conductive composition, the at least one layer of a conductive medium including an interfacing conductive composition that is configured to form an interfacing conductive layer to interface with a receiving surface, the interfacing conductive composition comprising a flowable mixture of a solvent with one of: a carbonaceous conductive composition, or an organic conductive composition; and
heat treating the at least one layer of a conductive medium to remove said solvent from each layer of the conductive medium, thereby forming a transferrable electrode on said release substrate,
wherein the transferrable electrode is releasably attached to the release surface of the release substrate.

The method of this third aspect of the present invention provides a new method of electrode fabrication which separately forms an electrode on a release substrate that can be subsequently transferred and applied to an electronic carrier substrate having selected underlying electronic layers configured for receipt of the transferrable electrode on a receiving surface thereon. This allows the electrode to be fabricated separately to the electronic carrier substrate, and therefore saving the electronic carrier substrate from the deleterious effects of heat treatment (annealing) and solvent leaching issues that may degrade the layers of the electronic carrier substrate if that electrode was formed/printed insitu.

Each layer of conductive medium is applied using a solution processing method. It should be understood that a solution processing method comprises a layer fabrication method in which the materials forming the layer are deposited while such materials are in solution (otherwise known as a “wet” processing method). This is in contrast to “dry” processing methods wherein such materials are deposited while in a gas or vapor phase. A conductive composition that is applied using a solution processing method typically comprises the conductive composition—typically a conductive material and a binder-mixed together within a solvent. Any suitable binder can be used. Examples of suitable binders are discussed above in relation to the first aspect of the present invention.

The conductive medium, the conductive material (and the conductive composition) can have any composition suitable for use in a solution printed flexible electronic device, for example a flexible optoelectronic device. In embodiment, the conductive medium comprises at least one layer of a conductive medium further comprises at least one further layer comprising a flowable mixture of a solvent with at least one of: a metallic-based composition, a carbonaceous conductive composition, or an organic conductive composition. It should be appreciated that the metallic-based composition, a carbonaceous conductive composition, and the organic conductive composition typically comprise metallic-based material and binder, a carbonaceous conductive material and binder, and an organic conductive material and binder respectively. Again, any suitable binder can be used. Examples of suitable binders are discussed above in relation to the first aspect of the present invention.

The transferrable electrode can be formed from a single conductive layer composition, or two or more conductive layer compositions. In embodiments, the transferrable electrode comprises at least two layers of conductive medium, and the applying step comprises:
applying at least one layer of a metallic-based conductive medium comprising a flowable mixture of a solvent with the metallic-based composition to the release substrate to form a first conductive layer; and
applying at least one layer of the interfacing conductive composition onto the first conductive layer to form an interfacing conductive layer.

The heat-treating step (also known as an annealing step) is used to remove solvent from the applied conductive medium, drying the layer. The heat-treating step is preferably conducted after a layer is applied, comprising heat treatment of the transferrable electrode after applying each conductive medium layer thereon. However, it should be appreciated that in other embodiments, two or more layers could also be applied before the combined layers are heat treated.

The transferable electrode preferably comprises at least two layers of the conductive medium comprising: at least one layer of a metallic-based conductive composition; and at least one layer of the interfacing conductive composition, wherein the outer layer comprises the interfacing conductive composition. Where two or more layers of different conductive materials are applied, it is preferred for the at least one layer of metallic-based conductive medium to be heat-treated prior to application of the interfacing conductive composition thereon. In this sense, the interfacing conductive composition is heat-treated after application on the first conductive layer.

The flowable mixture of the metallic-based conductive medium comprises a mixture of a solvent with the metallic-based composition. Suitable solvents include terpineol, dibutyl phthalate, butyl carbitol, dibutyl carbitol, turpentine oil, butyl glycol ether, butyl carbitol acetate, ethylene glycol ether acetate, tributyl citrate and tributyl phosphate, propylene glycol methyl ether acetatetoluene, diethylene glycol butyl ether, propanol, benzyl alcohol, isopropyl alcohol, ethanol, methanol, dimethylformamide, dimethylsulfoxide, chloroform, diethylene glycol derivatives, toluene, xylene isopropanol, ethyl acetate, water, chlorobenzene, or a combination thereof.

The flowable mixture of the carbonaceous conductive material comprises a mixture of a solvent with the metallic-based composition. Suitable solvents include terpineol, dibutyl phthalate, butyl carbitol, dibutyl carbitol, turpentine oil, butyl glycol ether, butyl carbitol acetate, ethylene glycol ether acetate, tributyl citrate and tributyl phosphate, propylene glycol methyl ether acetatetoluene, diethylene glycol butyl ether, propanol, benzyl alcohol, isopropyl alcohol, ethanol, methanol, dimethylformamide, dimethylsulfoxide, chloroform, diethylene glycol derivatives, toluene, xylene isopropanol, ethyl acetate, water, chlorobenzene, or a combination thereof.

The flowable mixture of the organic conductive material comprises a mixture of a solvent with the organic conductive composition. Suitable solvents include terpineol, dibutyl phthalate, butyl carbitol, dibutyl carbitol, turpentine oil, butyl glycol ether, butyl carbitol acetate, ethylene glycol ether acetate, tributyl citrate and tributyl phosphate, propylene glycol methyl ether acetatetoluene, diethylene glycol butyl ether, propanol, benzyl alcohol, isopropyl alcohol, ethanol, methanol, dimethylformamide, dimethylsulfoxide, chloroform, diethylene glycol derivatives, toluene, xylene isopropanol, ethyl acetate, water, chlorobenzene, or a combination thereof.

Various heat treatment regimens can be used. In some embodiments, heat treatment comprises heating the least one layer of a conductive medium at least 80° C. for at least 5 minutes, preferably at least 100° C. and more preferably at least 120° C. and more preferably 135° C. for at least 5 minutes. In embodiments, the heat treatment regime is conducted for 0 to 10 minutes, preferably 5 minutes. In some embodiments, the heat treatment comprises heating the least one layer of a conductive medium at 135° C. for 0 to 10 minutes, preferably 5 minutes.

Barrier encapsulation is useful for protecting the photovoltaic devices from degrading due to the interaction of the functional layers of the device with the ambient atmosphere (i.e. moisture and oxygen). The method of the present invention can be used to effectively apply the barrier encapsulant layer onto the device by itself or even as a multilayer system containing the barrier layer encapsulant, and the conductive layer or layers of the electrode. Thus, in some embodiments, the transferrable electrode further comprises at least one barrier film layer located between the release substrate and the at least one conductive layer. In such embodiments, the method further comprises:
applying at least one barrier film material composition between the release substrate and the at least one layer of a conductive medium to form at least one barrier film layer; and wherein the at least one layer of a conductive medium is printed onto the at least one barrier film layer.

The barrier film material composition can have any suitable composition. In embodiments, the barrier film material composition comprises a single thin-film barrier layer, or a multilayer thin-film barrier structure. This could be any suitable material that provides barrier properties including polymeric barrier materials such as ethylene-vinyl acetate (EVA), polydimethylsiloxane (PDMS), poly(1,3,5-trimethyl-1,3,5-trivinylcyclotrisiloxane) (pV3D3), or the like, or organic-inorganic nanocomposites such as silica-based materials including perhydropolysilazane (PHPS), or metallic oxide barrier layers such as aluminium oxide, silicon oxide, silicon nitride, titanium dioxide, or the like. Multilayer barrier structures could comprise a stack of alternating organic or inorganic layers or consecutive layers of organic or inorganic barrier materials such as those mentioned. It should be appreciated that the barrier film is preferably a very thin film which is too thin to handle. The barrier film has mechanical and physical properties which make it too thin to be a stand-alone film.

The conductive layer can have any suitable conductive composition:

Suitable metallic-based conductive layers include a conductive composition based on Au, Ag, Al, Mg, Cu or suitable alloys thereof or the like. In embodiments, the at least one metallic-based conductive layer comprises an Ag, Cu, Al or Au based layer. These layers can be formed using a metallic-based conductive medium such as a metallic-based paste, preferably an Ag, Cu or Al-containing paste.

The at least one organic conductive layer preferably comprises a charge transport layer, preferably a PEDOT-based conductive layer. Suitable PEDOT-based conductive layers include PEDOT or PEDOT containing compositions such as Poly(3,4-ethylenedioxythiophene):poly(styrene sulfonate) (PEDOT:PSS).

The carbonaceous conductive layer can be formed using any suitable conductive carbonaceous compositions. Suitable carbonaceous conductive layers include conductive carbonaceous compositions comprising carbon, graphite/carbon black, carbon nanotubes (CNTs), vapour-grown carbon fibers, graphene, or the like. In embodiments, the carbonaceous conductive layer comprises a porous, preferably macroporous carbonaceous conductive film.

The at least one carbonaceous conductive layer is preferably formed using a carbon-based/carbonaceous paste that typically comprises a conductive carbonaceous filler, a binder material and an organic solvent. In embodiments, the conductive carbonaceous filler is selected from graphite, carbon black, carbon nanotubes, vapour grown carbon fibres, graphene, or a combination thereof. In embodiments, the binder material is selected from ethyl cellulose, butyl cellulose, nitrocellulose, hydroxylcellulose, cellulose acetate butyrate, alkyd resins, epoxy resin, butadiene-styrene rubber, phenolic resins, acrylic resin, butyl carbitol, butadiene-styrene rubber, polyvinylpyrrolidone, polyacrylamide, cellulose derivatives, triethyl group hexyl phosphoric acid and lauryl sodium sulfate, cellulose-based polymers, or a combination thereof. In embodiments, the organic solvent is selected from terpineol, dibutyl phthalate, butyl carbitol, dibutyl carbitol, turpentine oil, butyl glycol ether, butyl carbitol acetate, ethylene glycol ether acetate, tributyl citrate and tributyl phosphate, propylene glycol methyl ether acetatetoluene, diethylene glycol butyl ether, propanol, benzyl alcohol, isopropyl alcohol, ethanol, methanol, dimethylformamide, dimethylsulfoxide, chloroform, diethylene glycol derivatives, toluene, xylene isopropanol, ethyl acetate, water, chlorobenzene, or a combination thereof.

As noted in the first aspect, the transferable electrode of the present invention is preferably a thin film electrode. In embodiments, the at least one conductive layer has a dry layer 1 μm to 100 μm, preferably from 10 to 80 μm, more preferably from 20 to 60 μm, and yet more preferably about 30 μm.

The release substrate can comprise any suitable material. In embodiments, the release substrate comprises a flexible polymer. In some embodiments, the release substrate comprises a flexible film, preferably a polymer film, such as a polyethylene terephthalate (PET) film, polyethylene naphthalate (PEN), polypropylene (PP), ethylene tetrafluoroethylene (ETFE) or could comprise a paper-based or a metal-based substrate such as paper or aluminium foil or the like.

As described above, the release surface provides a surface on which the transferrable electrode is releasably stuck, affixed or otherwise attached. The release substrate can be separated from the transferrable electrode once the transferrable electrode has interfaced with and been fixed (or otherwise adhered to) the receiving surface. The release surface on the release substrate can take a number of forms which allow the release substrate to be detached or otherwise removed from the transferable electrode.

In some embodiments, the release surface comprises a non-stick surface, preferably a non-stick coating or a low adhesion coating. Again, it should be appreciated that a non-stick surface and/or coating is surface engineered to reduce the ability of other materials to stick to it. In this sense, the coating has a composition that provides a low adhesion surface. As will be appreciated by the skilled person, a non-stick surface is inherently weakly susceptible to adhesion due to a low surface energy composition at its surface, and therefore does not require heat-activation to acquire non-stick properties. Non-stick surfaces may be provided by a low surface energy polymer, for example polymers selected from the group consisting of a fluorinated polymer, such as polytetrafluoroethylene (PTFE), and a silicone polymer, such as polydimethylsiloxane (PDMS). The non-stick surface may be a surface of a non-stick coating on the flexible release substrate. Suitable non-stick coatings are generally coatings of low surface energy polymers as described above. Alternatively, the flexible release substrate may comprise a self-supporting film of a suitable low surface energy polymer, and the non-stick surface is the surface of that film.

The release surface is preferably selected from the group consisting of a fluorinated polymer and a silicone polymer. Examples include polytetrafluoroethylene (PTFE), or silicone derivatives such as siloxane. In this embodiment, the release substrate is separable from the transferable electrode by delaminating/removing the transferable electrode from the non-stick surface

In other embodiments, the release surface comprises an activatable adhesive which can be activated to separate the transferrable electrode from the release substrate. Examples of suitable activatable adhesives include a heat-activatable adhesive polymer, preferably comprising a thermoplastic polymer selected from the group consisting of an ethylene-vinyl acetate (EVA) copolymer, a polyethylene, a polyethyleneoxide (PEO) and a polystyrene (PS). In this embodiment, the release substrate is separable from the transferable electrode when the activatable adhesive is activated, for example using heat for a heat activatable adhesive. Here, the activatable adhesive is heat-activatable at a temperature sufficient to release the release substrate from the transferrable electrode.

In other embodiments, the release surface comprises a low-cohesion sacrificial layer interposed between the flexible release substrate and the transferrable electrode, wherein the low-cohesion sacrificial layer has intrinsically low cohesion or has low cohesion when activated such that the flexible release substrate is separable from the transferrable electrode by breaking the low-cohesion sacrificial layer. The low-cohesion sacrificial layer can comprise at least one of: a low-cohesion organic non-polymeric solid; or an activatable adhesive which can be activated by heat or radiation to breaking the low-cohesion sacrificial layer and thereby separate the transferrable electrode from the release substrate. In this embodiment, the activatable adhesive can be a thermoplastic polymer, for example selected from the group consisting of an ethylene-vinyl acetate (EVA) copolymer, a polyethylene, a polyethyleneoxide (PEO) and a polystyrene (PS), or a light-depolymerizable polymeric composition, preferably selected from the group consisting of poly(phthalaldehyde) (PPHA) combined with photo acid generator (PAG), poly(acetal) s combined with PAG and polylactide (PLA) combined with TiO₂. In this embodiment, the release substrate is separable from the transferable electrode by (i) activating the activatable adhesive by heat or radiation and (ii) breaking the low-cohesion sacrificial layer.

Each layer of the conductive medium can be applied onto the release substrate and/or a subsequent layer to form the transferable electrode using any suitable method, for example at least one of: casting, doctor blading, blade coating, bar coating, screen printing, inkjet printing, pad printing, knife coating, meniscus coating, slot die coating, gravure printing, reverse gravure printing, kiss coating, micro-roll coating, curtain coating, slide coating, spray coating, flexographic printing, offset printing, rotatory screen printing, or dip coating. In exemplary embodiments, each layer of the conductive medium can be applied onto the release substrate and/or a subsequent layer using at least one of doctor blading; screen-printing, slot-die, gravure or reverse-gravure methods.

The flexible electrode of the present invention allows the range of pre-treatments (which are not possible with the conventional direct deposition method) on the electrodes prior to the pressing step. In embodiments, the method can further include at least one pre-treatment step to the transferrable electrode prior to applying the transferrable electrode onto the surface of the electronic carrier substrate selected from at least one of:
pre-pressing of the electrode to improve the inter-particular connectivity of the electrode as well the connectivity between the layers of conductive layers;
heat treating at elevated temperatures for prolonged time; or
at least one solvent exchange treatment.

Other advantages of the third aspect of the present invention, include a comparative reduction in the thickness of the formed electrode relative to electrodes printed onto an electronic carrier substrate, which can improve the flexibility as well as the specific weight of the devices.

The present invention also allows the electrodes to be fabricated and transferred onto the electronic carrier substrate in ambient air in comparison to conventional electrode deposition/fabrication methods involving expensive/low-throughput vacuum evaporation of top electrodes.

As noted above, the transferrable electrode typically comprises a thin film electrode that is so thin that it is not self-supporting, and therefore utilises the release substrate to be transported and manipulated. A fourth aspect of the present invention therefore involves transferring the transferrable electrode to the electronic carrier substrate via the release substrate (which typically functions as a sacrificial layer). In this sense, the transferrable thin film electrode is not configurable as a free-standing electrode that can be pressed onto the electronic carrier substrate directly, without a supporting substrate.

A fourth aspect of the present invention provides a method of forming a flexible electronic device, comprising:
A. providing a transferrable electrode arrangement in accordance with the first aspect of the present invention or a transferrable electrode as formed as in accordance with the method of the third aspect of the present invention;
B. providing an electronic carrier substrate having selected underlying electronic layers configured for receipt of the transferrable electrode on a receiving surface thereon;
C. applying the transferrable electrode onto the receiving surface of the electronic carrier substrate; and
D. removing the release substrate from the transferrable electrode, thereby producing an electronic device with the transferrable electrode applied thereon.

A further aspect of the present invention provides a method of forming a flexible electronic device, comprising:
A. forming a transferrable electrode in accordance with the third aspect of the present invention;
B. providing an electronic carrier substrate having selected underlying electronic layers configured for receipt of the transferrable electrode on a receiving surface thereon;
C. applying the transferrable electrode onto the receiving surface of the electronic carrier substrate; and
D. removing the release substrate from the transferrable electrode, thereby producing an electronic device with the transferrable electrode applied thereon.

In this fourth aspect, an electronic device-such as an optoelectronic device—is provided as an incomplete electronic carrier substrate having selected underlying electronic layers configured for receipt of the transferrable electrode on a receiving surface thereon. The electronic carrier substrate is typically a multilayered flexible electronic device. That electronic carrier substrate is capped with the transferrable electrode arrangement of the first aspect of the present invention, or as formed using the method of the third aspect of the present invention.

For practical use, the release substrate of the transferable electrode arrangement is sacrificial and is therefore preferably removed. The transferrable electrode arrangement (electrode on the release surface of the release substrate) enables that electrode layer, typically a thin film layer, to be safely transferred onto the electronic carrier substrate and then that sacrificial release substrate can then be separated or otherwise removed from the electrode stack, exposing the electrode and completing the fabrication of the electronic device. In this way fully printed, high-performing, and electronic devices can be produced using this method that is up-scalable for example using high-throughput roll-to-roll processes.

The transferrable electrode can be applied onto the receiving surface of the electronic carrier substrate in any suitable manner. One preferred application method is to press and/or compress the transferrable electrode onto the receiving surface of the electronic carrier substrate. The electrode film is transferred to the device via compression as the outer layer of the transferable electrode tends to bind to the upper most layer of the device. This binding is particularly evident when the outmost layer of the transferable electrode is a carbonaceous layer, and the top layer of the electronic carrier substrate is a charge transport layer. Any suitable compression/pressing process can be used. For example, the compression/pressing process can comprise roll pressing such as calendar press/laminator; uniaxial pressing; or isostatic pressing. In embodiments, the transferrable electrode is applied to the electronic carrier substrate by compression, preferably by a press arrangement, more preferably by a calendar press.

In various embodiments, the electronic device comprises an optoelectronic device. In these embodiments, the electronic carrier substrate preferably comprises:
a flexible substrate coated with a transparent conductive oxide coating;
a first charge transport layer located over the flexible substrate;
at least one photoactive layer located over the first charge transport layer; and
the receiving surface comprises the photoactive layer.

In these embodiments, the transferrable electrode preferably comprises a metallic-based conductive layer located over the release surface of the release substrate, and the organic conductive layer, preferably a charge transport layer, more preferably a PEDOT based conductive layer, located over the metallic-based conductive layer.

The multi-layered composition of the optoelectronic device can include the defined layers, and in some embodiments may include one or more additional layers. For example, in some embodiments, the optoelectronic device further comprises a second charge transport layer located over the flexible substrate located between the at least one photoactive layer and the transferrable electrode. In these embodiments, the electronic carrier substrate comprises:
a flexible substrate coated with a transparent conductive oxide coating;
a first charge transport layer located over the flexible substrate;
at least one photoactive layer located over the first charge transport layer; and
a second charge transport layer located over the at least one photoactive layer, and
the receiving surface comprises the second charge transport layer.

In these embodiments, the transferrable electrode preferably comprises a metallic-based conductive layer located over the release surface of the release substrate, and a carbonaceous (porous) conductive layer located over the metallic-based conductive layer.

It should be appreciated that other suitable layers could also be included in the layup depending on the desired configuration of the optoelectronic device.

As discussed previously, the first charge transport layer and second charge transport layer can have any suitable composition. In embodiments, at least one of the first charge transport layers or the second charge transport layer comprises at least one hole transporting layer, at least one electron transport layer. These layers can have a variety of compositions, depending on the desired optoelectronic device configuration as outlined in detail for the second aspect of the present invention. In exemplary embodiments, at least one of the first charge transport layers or the second charge transport layer can be selected from a variety of materials as discussed above. In embodiments, the first charge transport layers or the second charge transport layer is selected from at least one of: tin oxide, Spiro-OMeTAD, PPDT2FBT, or Phenyl-C61-butyric acid methyl ester (PCBM)/polyethylenimine ethoxylated (PEIE).

It should be noted that the composition of the first charge transport layer or the second charge transport layer may include one or more additives.

The photoactive layer can include a suitable photoactive composition. One exemplary photoactive layer comprises at least one perovskite layer. It should be appreciated that a photoactive perovskite layer comprises a light-absorbing perovskite semiconductor that consists essentially of crystallites of the perovskite. As will be discussed later in the specification, the term “perovskite”, as used herein, refers to (a) a material with a three-dimensional crystal structure related to that of CaTiO₃ or (b) a material comprising a layer of material, wherein the layer has a structure related to that of CaTiO₃. A perovskite material can be represented by the formula [A][M][X]₃, wherein [A] is at least one cation, [M] is at least one cation and [X] is at least one anion.

In embodiments, the transparent conductive oxide (TCO) coating is selected from at least one of tin-doped indium oxide (ITO), fluoride-doped tin oxide (FTO), doped zinc oxide such as aluminium doped zinc oxide (AZO), or indium doped cadmium-oxide.

The flexible substrate preferably comprises a polymer, preferably a polymer film, preferably a polyethylene terephthalate (PET), a polyethylene naphthalate (PEN), or a ethylene tetrafluoroethylene (ETFE) film, and more preferably a polyethylene terephthalate (PET) film.

The electronic carrier typically comprises a multilayer flexible electronic device formed through the sequential application of functional layers to a flexible substrate. In embodiments, the electronic carrier substrate is prepared by:
providing a flexible substrate coated with a transparent conductive oxide coating;
applying a first charge transport layer located over the flexible substrate;
applying at least one photoactive layer located over the first charge transport layer; and
optionally applying a second charge transport layer located over the at least one photoactive layer.

Similar to the layers of the electrode, each layer of the electronic carrier is applied over the subsequent layer using at least one of:
casting, doctor blading, blade coating, bar coating, screen printing, inkjet printing, pad printing, knife coating, meniscus coating, slot die coating, gravure printing, reverse gravure printing, kiss coating, micro-roll coating, curtain coating, slide coating, spray coating, flexographic printing, offset printing, rotatory screen printing, or dip coating.

The process of the present invention can be readily upscaled using roll-to-roll processing. The method of the present invention therefore preferably comprises a roll-to-roll printed electrode transfer method. The Inventors have found that electrodes produced using this method perform well compared to the electrodes produced using the conventional evaporated electrode method, making it very competitive in terms of performance.

A fifth aspect of the present invention provides an optoelectronic device formed using the method according to the fourth aspect of the present invention. The optoelectronic device can comprise a large range of photoactive devices such as photoelectric, photovoltaic and the like devices, including but not limited to photovoltaic cells, photoactive sensors, including photodetectors, or the like. An optoelectronic device according to the present invention could therefore comprise a photoactive device, such as a photovoltaic cell, a photoactive sensor or a light-emitting device. In some embodiments, the optoelectronic device can be selected from a photodiode; a phototransistor; a photomultiplier; a photo resistor; a photo detector; a light-sensitive detector; solid-state triode; a battery electrode; a light-emitting device; a light-emitting diode; a transistor; a solar cell; a laser; and a diode injection laser. The optoelectronic device preferably comprises at least one of a photovoltaic cell, or a photoactive sensor.

An optoelectronic device or photoactive device including a photoactive layer formed by the process of the present invention can be formed as an inverted structure or a conventional structure. For a perovskite optoelectronic device, a conventional structure is formed with a substrate having the following layers successively layered on a surface thereof: a transparent conductive oxide (TCO) layer, followed by an electron transporting layer; followed by the photoactive layer; followed by a hole transporting layer, and followed by a conductor layer (typically a metal). An inverted structure is formed with a substrate having the following layers successively layered on a surface thereof: a transparent conductive oxide (TCO) layer, followed by a hole transporting layer; followed by the photoactive layer; followed by an electron transporting layer, and followed by a conductor layer (typically a metal). A hole-transporting (p-type) layer can be any hole-conducting material with an appropriate valence band edge. For an organic optoelectronic device, a conventional structure is formed with a substrate having the following layers successively layered on a surface thereof: a transparent conductive oxide (TCO) layer, followed by a hole transporting layer; followed by an organic (BHJ) photoactive layer; followed by an electron transporting layer, and followed by a conductor layer (typically a metal). An inverted structure is formed with a substrate having the following layers successively layered on a surface thereof: a transparent conductive oxide (TCO) layer, followed by an electron transporting layer; followed by the organic (BHJ) photoactive layer; followed by a hole transporting layer, and followed by a conductor layer (typically a metal).

The transferrable electrode of the present invention can be applied to a variety of printed electronics, including flexible photovoltaic devices. Suitable photovoltaic devices include organic photovoltaic arrangements and perovskite photovoltaic arrangements.

The method/process and electrode of the present invention can be applied to the manufacture of the following printed electronics:
Printed electrodes for flexible photovoltaics including thin-film photovoltaic devices.
Printed electronic sensors.
Printed flexible electronics, including flexible optoelectronic devices such as OLEDs, diodes.

The process of producing an electronic device of the present invention preferably provides the following advantages:
Eliminates expensive/low-throughput vacuum evaporation of top electrodes.
Compatible with Roll-to-roll production, and thus can be readily upscaled.
Produces high-performing fully printed photovoltaics.

### BRIEF DESCRIPTION OF THE DRAWINGS

The present invention will now be described with reference to the figures of the accompanying drawings, which illustrate particularly preferred embodiments of the present invention, wherein:

FIG. 1 is a perspective view of a process of forming a flexible electronic device using a transferrable electrode according to one embodiment of the present invention.

FIG. 2 is a schematic view of the layer of a flexible electronic device that includes a transferrable electrode according to one embodiment of the present invention.

FIG. 3 provides a side view of the flexible electronic device shown in FIG. 2 illustrating the comprising layers of the device.

FIG. 4 (A) is a photograph of an optoelectronic device according to one embodiment of the present invention with the release substrate having already been removed.

FIG. 4(B) is a photograph of an optoelectronic device shown in FIG. 4, with the release substrate being removed from the transferable electrode thereon.

FIG. 5 provides a schematic of a first methodology for forming an optoelectronic device according to a first embodiment of the present invention, showing the steps of: (A) printing the layers of the carrier substrate (partially fabricated device); (B) the fully printed carrier substrate; (C) printing the layers of the transferrable electrode; (D) the fully printed transferable electrode; (E) applying the transferable electrode to the carrier substrate; (F) the formed optoelectronic device, with sacrificial release substrate attached; (G) removal of the sacrificial release substrate from the transferable electrode; and (H) the final optoelectronic device.

FIG. 6 provides a schematic of a second methodology for forming an optoelectronic device according to a first embodiment of the present invention, showing the steps of: (A) printing the layers of the carrier substrate (partially fabricated device); (B) the fully printed carrier substrate; (C) printing the layers of the transferrable electrode; (D) the fully printed transferable electrode; (E) applying the transferable electrode to the carrier substrate; (F) the formed optoelectronic device, with sacrificial release substrate attached; (G) removal of the sacrificial release substrate from the transferable electrode; and (H) The final optoelectronic device.

FIG. 7 provides a schematic of a third methodology for forming an optoelectronic device according to a first embodiment of the present invention, showing the steps of: (A) printing the layers of the carrier substrate (partially fabricated device); (B) the fully printed carrier substrate; (C) printing the layers of the transferrable electrode; (D) the fully printed transferable electrode; (E) applying the transferable electrode to the carrier substrate; (F) the formed optoelectronic device, with sacrificial release substrate attached; (G) removal of the sacrificial release substrate from the transferable electrode; and (H) the final optoelectronic device.

FIG. 8 provides Scanning Electron Microscope (SEM) images of a) the Ag film, and b) the carbon film of the transferrable electrode taken before lamination transfer onto the PSC precursor stack.

FIG. 9 provides a plot showing sheet resistance measurements for varying carbon film thicknesses taken before lamination transfer onto the PSC precursor stack.

FIG. 10 illustrates. a) J-V curves, b) MPP tracking, and c) EQE and cumulative Jsc for the champion flexible PSC with printed DPD Ag/carbon electrode showing the reverse and forward scan under 1-sun illumination, d) J-V curves for the champion PSC with a printed DPD electrode and the champion PSC with an evaporated Au electrode, and e) box plot of PCE results for PSCs with a printed DPD electrode or an Au-electrode (inset (i) and (ii): photos of the devices).

FIG. 11 provides a) an illustration of the flexible encapsulation architecture used in the operational stability test of the flexible PSC with printed DPD electrode; b) MPP tracking of a flexible PSC with printed DPD electrode encapsulated with flexible polymeric barrier materials under continuous illumination in the ambient laboratory environment (inset (i): photo of an encapsulated PSC); c) Illustrations showing the device in convex (left) and concave (right) bending regimes indicating the stress imposed on the top printed electrode, and d) cyclic bending results comparing the normalized PCE devices with a printed DPD electrode or an evaporated Au electrode.

FIG. 12 provides photographic images (a) the in-house built bending apparatus; and b) the 10 mm bending radius used for the mechanical stability test over 3000 bending cycles in the inhouse built bending machine shown in (a).

FIG. 13 illustrates normalized resistance results for the printed DPD Ag/carbon layers under various bending regimes, measured using a 4-point probe.

### DETAILED DESCRIPTION

The present invention provides a method of forming a transferrable thin film electrode arrangement, the transferrable thin film electrode, and flexible electronic devices such as optoelectronic devices that incorporate that transferrable thin film electrode.

The transferrable electrode arrangement comprises a flexible release substrate and one or more conductive layers on the flexible release substrate configured to interface with a electronic carrier substrate. In use, the flexible release substrate is separable from the transferrable electrode after the electronic carrier substrate is adhered to an interfacing layer of the transferrable electrode.

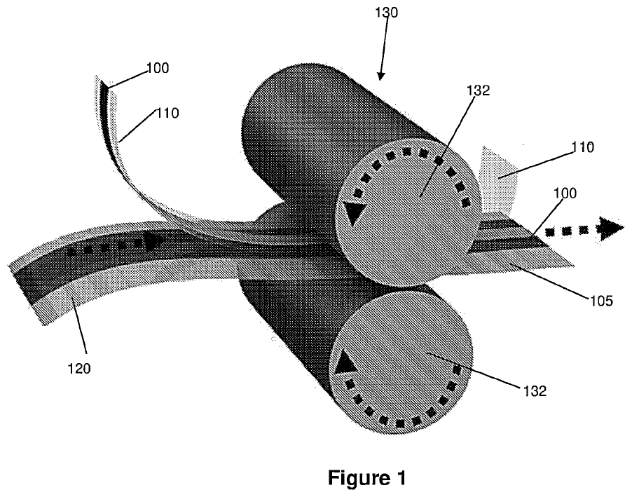

One embodiment of the transferrable electrode 100 of the present invention is shown in FIGS. 1 to 4. The transferrable electrode 100 is fabricated as a thin electrode film that has a thickness that is not self-supporting without being supported on a release substrate 110. In this sense, the transferrable electrode 100 is physically unstable—i.e. the thin electrode film cannot stand freely by itself.

The transferrable electrode 100 is prepared by applying at least one layer of a conductive medium over a release surface, for example a non-stick coating (as illustrated), of a release substrate 110 comprising a flexible polymer film to form a conductive layer thereon. The conductive layer is formed using a solution processing method, in which a conductive composition is deposited as a layer using a wet method. The conductive medium (and the solution process conductive composition) can have any composition suitable for use in a solution printed flexible electronic device, for example a flexible optoelectronic device. In exemplary embodiments of the present invention, the conductive medium comprises a flowable mixture of a solvent with a metallic-based composition, a carbonaceous conductive composition, and/or an organic conductive composition as discussed previously. The transferrable electrode can be formed from a single conductive layer composition, or two or more conductive layer compositions. In the embodiment illustrated in FIGS. 1 to 4, the transferrable electrode is a bi-layered electrode including both a carbonaceous and a metal-based conductive layer, with a layer of a metallic-based conductive medium applied onto a release/carrier substrate 110 to form a first conductive layer 112; and a layer of a carbonaceous conductive material, or an organic conductive material applied onto the first conductive layer to form a second conductive layer 114.

It should be appreciated that whilst the release substrate is described as comprising a flexible polymer, preferably a flexible polymer film in this embodiment, it could equally comprise other flexible materials such as paper or aluminium foil or the like.

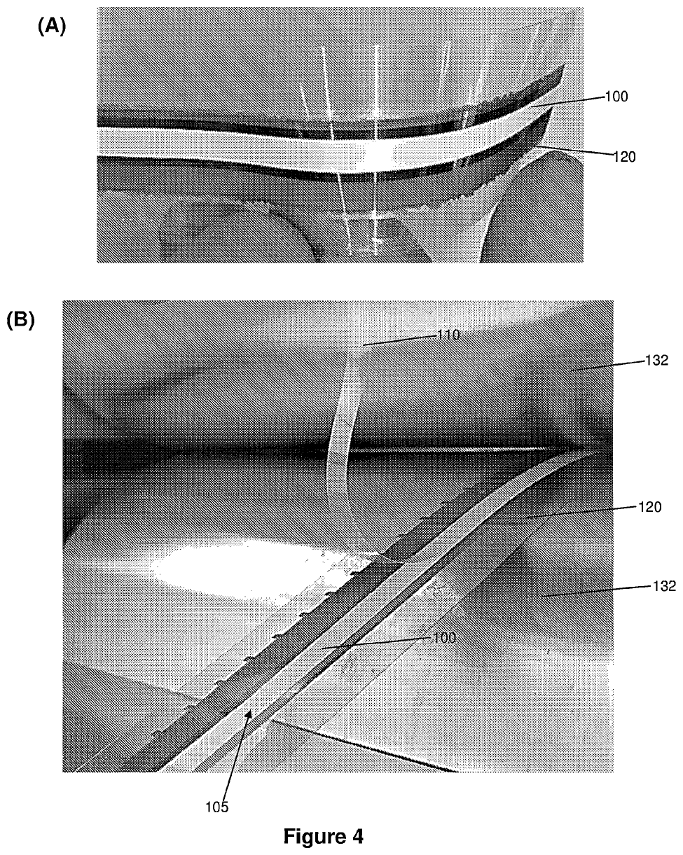

Each layer of the applied conductive medium (the metallic-based conductive medium and the carbonaceous conductive material) is heat-treated to remove said solvent from the layer. Once the conductive material forming the electrode is suitably heat-treated, with all solvents removed, the electrode 100 and release substrate film 110 arrangement is applied to an electronic carrier substrate 120—a partially prepared flexible electronic device. This involves applying a compressive force to press the electrode onto a receipt layer of the electronic carrier substrate. In FIGS. 1 and 4, a calendar press 130 which includes two opposing rollers 132 is used to apply the compressive force to press the electrode onto the electronic carrier substrate 120.

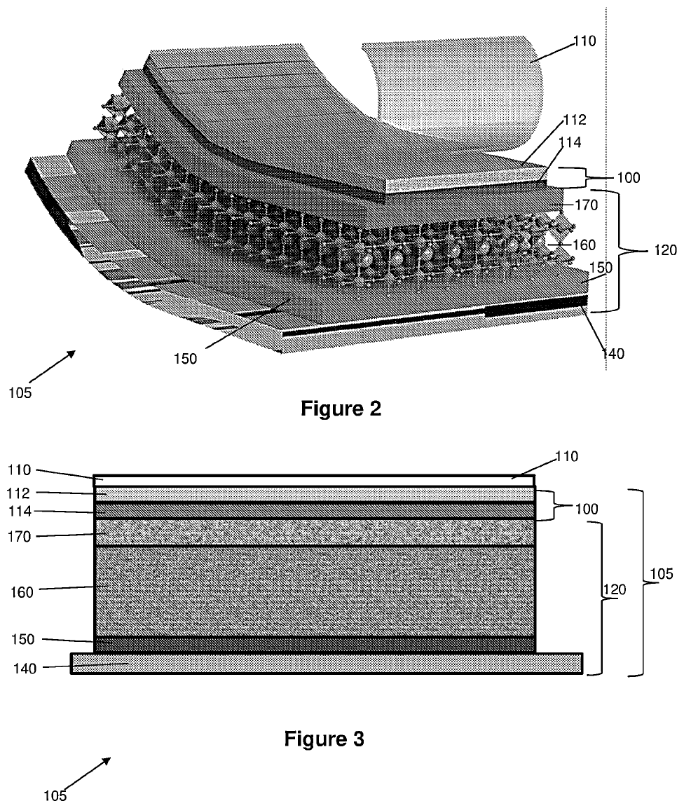

The electronic carrier substrate 120 illustrated in FIGS. 1 to 4 comprises a partially prepared flexible photovoltaic device. As best shown in FIGS. 2 and 3, the electronic carrier substrate 120 comprises a flexible substrate (typically a flexible polymer film) coated with a transparent conductive oxide coating 140, with a first charge transport layer 150 located over the flexible substrate 140; followed by a photoactive layer 160 located over the first charge transport layer 150; and then an optional second charge transport layer 170 located over the photoactive layer 160. It should be appreciated that the multi-layered composition of the optoelectronic device can include the defined layers, and in some embodiments may include one or more additional layers depending on the desired configuration of flexible photovoltaic device 105.

Each layer of the transferable electrode 100 and electronic carrier substrate 120 can be formed by one of many coating techniques that are known in the art including casting, doctor blading, blade coating, bar coating, screen printing, inkjet printing, pad printing, knife coating, meniscus coating, slot die coating, gravure printing, reverse gravure printing, kiss coating, micro-roll coating, curtain coating, slide coating, spray coating, flexographic printing, offset printing, rotatory screen printing, dip coating, direct or physical application or the like. It should be appreciated that a person skilled in the art would be able to adopt a suitable technique to apply each layer based on techniques known in the art. In this sense, each layer of the transferable electrode 100, and preferably also each layer of the carrier substrate 120, is applied using a solution processing method.

The transferable electrode 100 is transferred onto the electronic carrier substrate 120 using compression. Where the lower layer is a carbonaceous conductive composition 114, that layer 114 tends to bind to the upper most layer of the device—in the illustrated embodiment, the uppermost charge transport layer 170 of the electronic carrier substrate 120. Once passed through the calendar press 130, the non-stick release substrate 110 can then be peeled off the electrode stack, exposing the transferable electrode 100 and completing the fabrication of the flexible photovoltaic device 105. In this way, fully-printed, high-performing, and flexible photovoltaic (PV) devices 105 can be produced using this method that is up-scalable using high-throughput roll-to-roll processes.

In this new method, the transferable electrode 100 is printed and heat-treated (annealed) separately before it is pressed onto the electronic carrier substrate 120 to avoid any unnecessary interaction of the layup of the electronic carrier substrate 120 with the solvents. Additionally, the transferable electrode 100 does not require any further heat treatment after being pressed onto the device thereby avoiding potential degradation of some underlying layers of the electronic carrier substrate 120 had heat treatment been required.

This method also can significantly reduce the thickness of the printed electrode to improve the flexibility as well as the specific weight of the devices.

The conductive layer can have any suitable conductive composition as previously outlined and described. Similarly, the layers of the electronic carrier substrate 120 can have any suitable composition as previously outlined and described.

In various embodiments of the illustrated flexible photovoltaic device 105, the photoactive layer 160 is a perovskite material. The skilled person will appreciate that a perovskite material can be represented by the formula [A][M][X]₃, wherein [A] is at least one cation, [M] is at least one cation and [X] is at least one anion. When the perovskite comprises more than one A cation, the different A cations may be distributed over the A sites in an ordered or disordered way. When the perovskite comprises more than one M cation, the different M cations may be distributed over the M sites in an ordered or disordered way. When the perovskite comprises more than one X anion, the different X anions may be distributed over the X sites in an ordered or disordered way. The symmetry of a perovskite comprising more than one A cation, more than one M cation or more than one X cation, will be lower than that of CaTiO₃. Perovskite is a crystalline compound. Thus, the layer of the perovskite semiconductor without open porosity typically consists essentially of crystallites of the perovskite. In a perovskite-type photoactive device, such as a photovoltaic cell, the photoactive layer can comprise an organic-inorganic perovskite-structured semiconductor. However, it should be appreciated that in some embodiments, the photoactive layer can be all inorganic, for example, CsPbI₃.

As mentioned in the preceding paragraph, the term “perovskite”, as used herein, refers to (a) a material with a three-dimensional crystal structure related to that of CaTiO₃ or (b) a material comprising a layer of material, wherein the layer has a structure related to that of CaTiO₃. Although both of these categories of perovskite may be used in the devices according to the invention, it is preferable in some circumstances to use a perovskite of the first category, (a), i.e. a perovskite having a three-dimensional (3D) crystal structure. Such perovskites typically comprise a 3D network of perovskite unit cells without any separation between layers. Perovskites of the second category, (b), on the other hand, include perovskites having a two-dimensional (2D) layered structure. Perovskites having a 2D layered structure may comprise layers of perovskite unit cells that are separated by (intercalated) molecules; an example of such a 2D layered perovskite is [2-(I-cyclohexenyl)ethylammonium]2PbBr₄. 2D layered perovskites tend to have high exciton binding energies, which favours the generation of bound electron-hole pairs (excitons), rather than free charge carriers, under photoexcitation. The bound electron-hole pairs may not be sufficiently mobile to reach the p-type or n-type contact where they can then transfer (ionise) and generate free charge. Consequently, in order to generate free charge, the exciton binding energy has to be overcome, which represents an energetic cost to the charge generation process and results in a lower voltage in a photovoltaic cell and a lower efficiency. In contrast, perovskites having a 3D crystal structure tend to have much lower exciton binding energies (on the order of thermal energy) and can therefore generate free carriers directly following photoexcitation. Accordingly, the perovskite semiconductor employed in the devices and processes of the present invention is preferably a perovskite of the first category, (a), i.e. a perovskite which has a three-dimensional crystal structure. This is particularly preferable when the optoelectronic device is a photovoltaic device.

As used herein, the term “thickness” refers to the average thickness of a component of an electronic device. As noted above the transferable electrode of the present invention is preferably a thin film electrode, which is so thin that it is not self-supporting. In embodiments, the at least one conductive layer has a dry layer thickness from 1 μm to 100 μm, preferably from 10 to 80 μm, more preferably from 20 to 60 μm, and yet more preferably about 40 μm.

The release substrate 110 provides a surface (the release surface) on which the transferable electrode 100 is releasably stuck, affixed or otherwise attached. The release substrate 110 can be separated from the transferable electrode 100, in the above embodiment, after the carbonaceous conductive composition 114 of the transferable electrode 100 binds to the uppermost charge transport layer 170 of the electronic carrier substrate 120.

In various embodiments of the illustrated flexible photovoltaic device 105, the release/carrier substrate 110 comprises a non-stick surface so that the flexible release substrate is readily separable from the transferrable electrode by delamination therefrom. The non-stick surface may be a surface of a non-stick coating on the flexible release substrate. Suitable non-stick coatings are generally low surface energy polymers, for example polymers selected from the group consisting of a fluorinated polymer, such as polytetrafluoroethylene (PTFE), and a silicone polymer, such as polydimethylsiloxane (PDMS). Alternatively, the flexible release substrate may comprise a self-supporting film of a suitable low surface energy polymer, and the non-stick surface is the surface of that film.

It should be appreciated that the release substrate 110 could equally include a low-cohesion sacrificial layer interposed between the release substrate 110 and the conductive layers of the transferrable electrode. As used herein, the low-cohesion sacrificial layer is a layer having cohesive forces within the layer which are intentionally weaker than the adhesive forces between other layers in the transferable electrode 100 and the electronic carrier substrate 120, and the cohesive forces within other layers, in the multi-layered structure. The low-cohesion sacrificial layer is either an intrinsically low-cohesion layer, i.e. at room temperature, or has suitably low cohesion when activated. In either case, the flexible release substrate is separable from the transferrable electrode by preferentially breaking the low-cohesion sacrificial layer. It will be appreciated, however, that the low-cohesion sacrificial layer nevertheless requires sufficient cohesive integrity and adhesive character so that the flexible release substrate can adhere to and support the transferrable electrode during fabrication and while transferring the transferable electrode 100 onto the electronic carrier substrate 120.

The low-cohesion sacrificial layer transparent is preferably a very thin layer, for example having a thickness of less than 100 nm, or less than 50 nm, or less than 20 nm. In some embodiments, the low-cohesion sacrificial layer is conductive due to the incorporation of a conductive component such as a metal, a metal oxide, and a conductive polymer or polymer composite (such as poly(3,4-ethylenedioxythiophene) polystyrene sulfonate, i.e. PEDOT:PSS). The inclusion of a conductive component may advantageously mitigate any loss of electrical conductivity through the surface of the first transparent conductive layer if residues of the low-cohesion sacrificial layer remain on that layer following the separation and removal of the flexible release substrate.

In some embodiments, the low-cohesion sacrificial layer comprises a low-cohesion organic non-polymeric solid, such as a wax. In some embodiments, the low-cohesion sacrificial layer comprises an activatable adhesive. The activatable adhesive may be activated, to sufficiently reduce the cohesion of the sacrificial layer, by any suitable external stimulus applied on command, such as heat or radiation. The release substrate can therefore be separated from the transferrable electrode by activating the activatable adhesive by heat or radiation and breaking the low-cohesion sacrificial layer.

In some embodiments, the activatable adhesive in the sacrificial layer is a heat-activatable adhesive, such as a thermoplastic polymer selected from the group consisting of an ethylene-vinyl acetate (EVA) copolymer, a polyethylene, a polyethyleneoxide (PEO) and a polystyrene (PS). The thermoplastic polymer responds to the application of heat by melting or softening, thus lowering the cohesion of the sacrificial layer as required. Preferably, the activation occurs at temperatures which can be achieved when interfacing/adhering (for example pressing) the transferable electrode 100 onto the electronic carrier substrate 120, and without damaging other layers in the device. In some embodiments, the sacrificial layer is heat-activatable, to sufficiently lower the cohesion thereof, at a temperature in the range of 50° C. to 170° C., such as in the range of 90° C. to 140° C.

In other embodiments, the activatable adhesive in the sacrificial layer is a light-depolymerizable polymeric composition, optionally including a suitable photoinitiator or photocatalyst. Examples include a polymeric composition selected from the group consisting of poly(phthalaldehyde) (PPHA) combined with photo acid generator (PAG), poly(acetal) s combined with PAG and polylactide (PLA) combined with TiO₂. The light-depolymerizable polymeric composition responds to irradiation with a suitable wavelength light by depolymerising or decrosslinking, thus lowering the cohesion of the sacrificial layer as required.

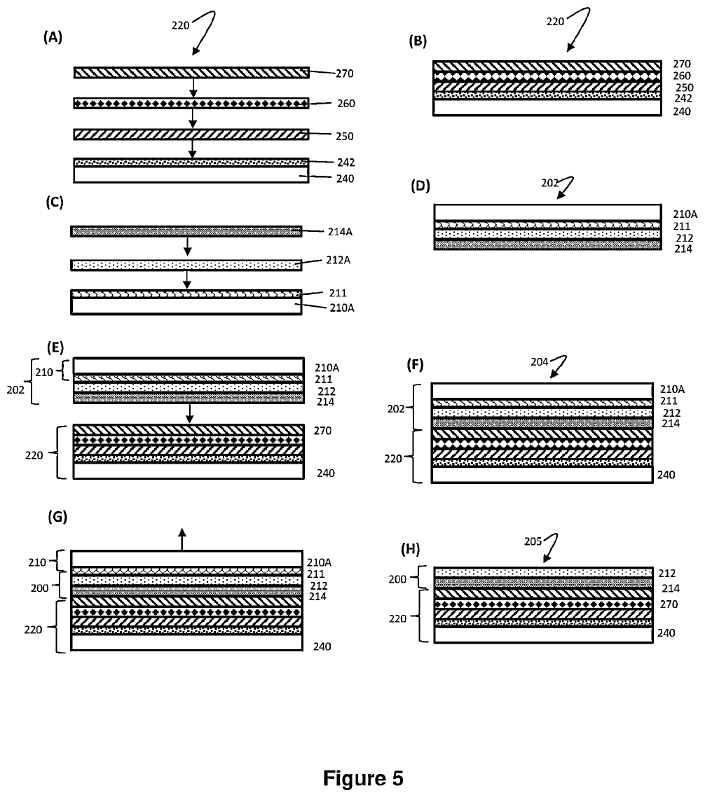

FIGS. 5 to 7 illustrate three different methodology steps for forming flexible perovskite devices that include a transferable electrode of the present invention. The flexible perovskite devices can be fabricated using a variety of processes, including readily up-scalable roll-to-roll (R2R) compatible printing and coating processes.

### Methodology 1 (FIG. 5)

FIG. 5 illustrates a first embodiment of an electronic device, in this case a perovskite photovoltaic cell 205 (FIG. 5H) that can be manufactured using embodiments of the transferable electrode of the present invention.

In a first step, an electronic carrier substrate—a partially fabricated flexible perovskite solar device 220 (without the outer electrode layer) is fabricated. As shown in FIG. 5A, a flexible substrate 240 such as PET is provided and is coated with a transparent conductive oxide (TCO) coating 242 such as indium-tin-oxide (ITO). A first charge transport layer (CTL) 250 is then deposited onto the substrate via reverse-gravure or slot-die coating techniques. The photoactive perovskite layer 260 is deposited on top of this CTL 250 via slot-die coating. Following a brief heat treatment (annealing) step at a temperature of at least 60° C., a second CTL 270 is slot-die coated on top of the perovskite film 260. This results in a partially fabricated flexible perovskite solar device 220 which has been fully deposited up to the top CTL 270 (FIG. 5B).

Instead of depositing the top-electrode directly on the CTL layer 270, the printed top-electrode 200 is prepared separately on a release substrate 210. As shown in FIG. 5C, the release substrate 210 (flexible polymer 210A such as PET with non-stick coating 211 such as polytetrafluoroethylene (PTFE), or silicone derivatives such as siloxane or the like) is initially fixed to a flat platform (not illustrated) before uniformly coating the surface with a metallic-based paste (for example a highly conductive Ag-based paste) 212A. This can be done using a range of printing and coating methods such as doctor blading, blade coating, bar coating, screen printing, slot die coating, inkjet printing, etc. Once coated, the release substrate 210 is transferred onto a hot plate (not illustrated) to heat treat/anneal the coated conductive film at a temperature of at least 100° C. to form a thin metal-based conductive film 212 (FIG. 5D). Following this annealing step, the metal layer coated film is transferred back onto the flat platform (not illustrated) and a uniform layer of carbon-based/carbonaceous paste 214A is coated on the top of the thin conductive film 212. Once coated, the release substrate 210 is transferred onto a hot plate (not illustrated) to heat treat/anneal the coated conductive film at a temperature of at least 100° C. to form a carbon-based conductive film 214 (FIG. 5D). The annealing stages of both the conductive and carbon-based paste evaporate any existing solvents that may otherwise ingress into the active layers of the flexible perovskite solar cell and result in device degradation. This results in a transfer arrangement 202 comprising a bi-layered flexible electrode 200 coated on the release substrate 210.

As illustrated in FIG. 5E, the transfer arrangement 202 (release substrate 210 and bi-layered flexible electrode 200) is then pressed onto the top CTL 270 of the partially fabricated flexible perovskite solar device 220. This can be achieved via roll-lamination techniques for example using a calendar press, uniaxial pressing or isostatic pressing to form the release coated device 204 (FIG. 5F).

In this embodiment, the carbon-based conductive film 214 provides interfacing conductive layer which directly engages with and is attached to (via pressing) with the receiving surface (the top CTL 270) of the partially fabricated flexible perovskite solar device 220. The carbon-based conductive film 214 provides a suitable composed layer to interface between the bi-layered flexible electrode 200 and the partially fabricated flexible perovskite solar device 220.

Following compression, the release substrate 210 (flexible polymer 210A with non-stick coating 211) is removed, for example, peeled off, from the top of the printed electrode (FIG. 5G), exposing the conductive film for electrical connection and resulting in the final flexible perovskite solar device 205.

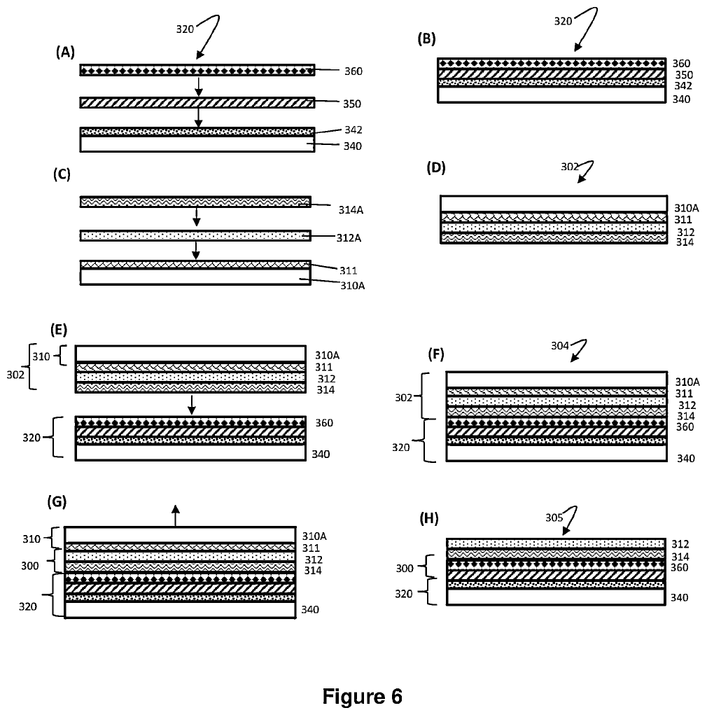

### Methodology 2 (FIG. 6)

FIG. 6 illustrates a second embodiment of an electronic device, in this case a perovskite photovoltaic cell 305 (FIG. 6H) that can be manufactured using embodiments of the transferable electrode of the present invention.

In a first step, an electronic carrier substrate—a partially fabricated flexible perovskite solar device 320 (without the outer electrode layer and underlying CTL layer) is fabricated. As shown in FIG. 6A, a flexible substrate 340 such as PET is provided and is coated with a transparent conductive oxide (TCO) coating 342 such as indium-tin-oxide (ITO). A first charge transport layer (CTL) 350 is then deposited onto the substrate via reverse-gravure or slot-die coating techniques. The photoactive perovskite layer 360 is deposited on top of this CTL 360 via slot-die coating. This results in a partially fabricated flexible perovskite solar device 320 which has been fully deposited up to the top perovskite layer 360 (FIG. 6B).

Instead of depositing the top CTL layer and the top electrode directly on the perovskite layer 360, the printed top CTL layer (organic conductor layer/film 314) and top electrode (metal-based conductive film 312) are prepared separately on a release substrate 310. As shown in FIG. 6C, the release substrate 310 (flexible polymer 310A such as PET with non-stick coating 311 such as polytetrafluoroethylene (PTFE), or silicone derivatives such as siloxane or the like) is initially fixed to a flat platform (not illustrated) before uniformly coating the surface with a metallic-based paste (for example a highly conductive Ag-based paste) 312A. This can be done using a range of printing and coating methods such as doctor blading, blade coating, bar coating, screen printing, slot die coating, inkjet printing, etc. Once coated, the release substrate 310 is transferred onto a hot plate (not illustrated) to heat treat/anneal the coated conductive film at a temperature of at least 100° C. to form a thin metal-based conductive film 312 (FIG. 6D). Following this annealing step, the metal layer coated film is transferred back onto the flat platform (not illustrated) and a uniform layer of an organic conductor (for example PEDOT or a PEDOT:PSS solution) 314A is coated on the top of the thin conductive film 312. Once coated, the release substrate 310 is transferred onto a hot plate (not illustrated) to heat treat/anneal the coated conductive film at a temperature of at least 80° C. to form an organic conductive film 314 (FIG. 6D). In the annealing stages, both conductive pastes evaporate any existing solvents. This results in a transfer arrangement 302 comprising a bi-layered flexible electrode 300 coated on the release substrate 310.

As illustrated in FIG. 6E, the transfer arrangement 302 (release substrate 310 and bi-layered flexible electrode 300) is then pressed onto the top perovskite layer 360 of the partially fabricated flexible perovskite solar device 320. This can be achieved via roll-lamination techniques (for example a calendar press), uniaxial pressing or isostatic pressing to form the release coated device 304 (FIG. 6F).

In this embodiment, the organic conductive film 314 provides interfacing conductive layer which directly engages with and is attached to (via pressing) with the receiving surface (the top perovskite layer 360) of the partially fabricated flexible perovskite solar device 320. The organic conductive film 314 provides a suitable composed layer to interface between the bi-layered flexible electrode 300 and the partially fabricated flexible perovskite solar device 320.

Following compression, the release substrate 310 (flexible polymer 310A with non-stick coating 311) is removed, for example, peeled off, from the top of the printed electrode (FIG. 6G), exposing the conductive film for electrical connection and resulting in the final flexible perovskite solar device 305.

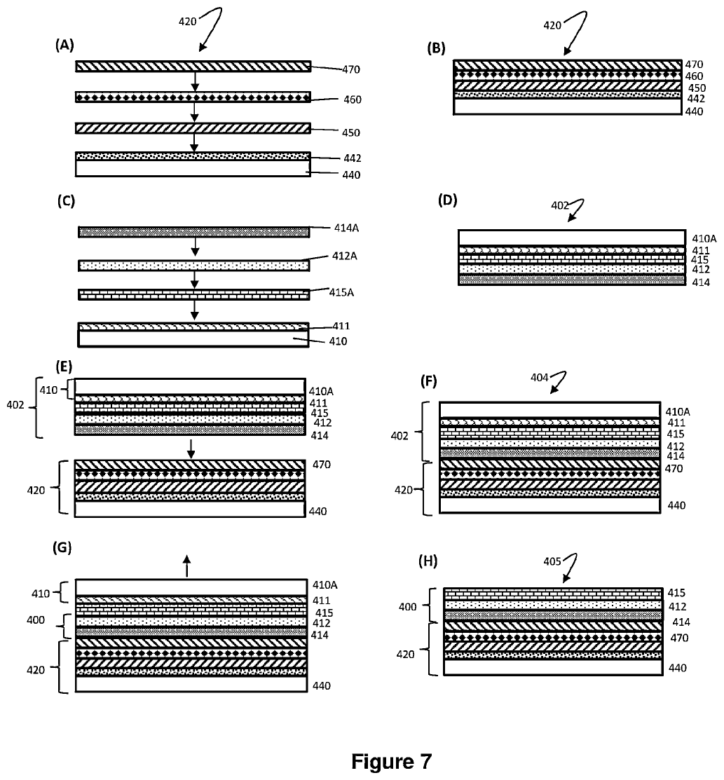

### Methodology 3 (FIG. 7)

Barrier encapsulation is useful for protecting the photovoltaic devices from degrading due to the interaction of the functional layers of the device with moisture and oxygen in the ambient atmosphere. Direct deposition of the barrier material on the printed PV devices is one of the ways to apply the barrier layer on the devices. However, direct deposition is impossible when the barrier formulations contain any solvents which react with the functional layers. The method of the present invention can be used to effectively apply the barrier encapsulant layer onto the device by itself or even as a multilayer system containing the encapsulant, Ag electrode, and the carbon electrode.

FIG. 7 illustrates a third embodiment of an electronic device, in this case, a perovskite photovoltaic cell 405 (FIG. 7H) that can be manufactured using embodiments of the transferable electrode of the present invention.

In a first step, an electronic carrier substrate—a partially fabricated flexible perovskite solar device 420 (without the outer electrode layer) is fabricated. As shown in FIG. 7A, a flexible substrate 440 such as PET is provided and is coated with a transparent conductive oxide (TCO) coating 442 such as indium-tin-oxide (ITO). A first charge transport layer (CTL) 450 is then deposited onto the substrate via reverse-gravure or slot-die coating techniques. The photoactive perovskite layer 460 is deposited on top of this CTL 450 via slot-die coating. Following a brief heat treatment (annealing) step at a temperature of at least 100° C., a second CTL 470 is slot-die coated on top of the perovskite film 460. This results in a partially fabricated flexible perovskite solar device 420 which has been fully deposited up to the top CTL 470 (FIG. 7B).

Instead of depositing the top-electrode directly on the CTL layer 470, the printed top-electrode 400 is prepared separately on a release substrate 410. As shown in FIG. 5C, the release substrate 410 (flexible polymer 410A such as PET with non-stick coating 411 such as polytetrafluoroethylene (PTFE), or silicone derivatives such as siloxane or the like) is initially fixed to a flat platform (not illustrated) before uniformly coating the surface with a barrier material formulation 415A, for example, ethylene-vinyl acetate (EVA). This can be done using a range of printing and coating methods such as doctor blading, blade coating, gravure coating, reverse gravure coating, bar coating, screen printing, slot die coating, inkjet printing, etc. Once coated, the release substrate is transferred to a hot plate (not illustrated) to heat treat/anneal the coated barrier film at a temperature of at least 60° C. to form a barrier film 415 thereon (FIG. 7D). Following this annealing stage, the film is transferred back to the platform (not illustrated) and a uniform layer of a metallic-based paste (for example a highly conductive Ag-based paste) 412A is applied on top of the barrier film 415. This can be done using a range of printing and coating methods such as doctor blading, blade coating, bar coating, screen printing, slot die coating, inkjet printing, etc. Once coated, the release substrate 410 is transferred onto a hot plate (not illustrated) to heat treat/anneal the coated conductive film at a temperature of at least 60° C. to form a thin metal-based conductive film 412 thereon (FIG. 7D). Following this annealing step, the metal layer coated film is transferred back onto the flat platform (not illustrated) and a uniform layer of carbon-based/carbonaceous paste 414A is coated on the top of the thin conductive film 412. Once coated, the release substrate 410 is transferred onto a hot plate (not illustrated) to heat treat/anneal the coated conductive film at a temperature of at least 60° C. to form a carbon-based conductive film 414 (FIG. 7D). The annealing stages of both the conductive and carbon-based paste evaporate any existing solvents that may otherwise ingress into the active layers of the flexible perovskite solar cell and result in device degradation. This results in a transfer arrangement 402 comprising a bi-layered flexible electrode 400 coated on the barrier film 415 and release substrate 410.

As illustrated in FIG. 7E, the transfer arrangement 402 (release substrate 410, barrier film 415 and bi-layered flexible electrode 400) is then pressed onto the top CTL 470 of the partially fabricated flexible perovskite solar device 420. This can be achieved via roll-lamination techniques (for example a calendar press), uniaxial pressing or isostatic pressing to form the release coated device 404 (FIG. 7F).

In this embodiment, the carbon-based conductive film 414 provides interfacing conductive layer which directly engages with and is attached to (via pressing) with the receiving surface (the top CTL 470) of the partially fabricated flexible perovskite solar device 420. The carbon-based conductive film 414 provides a suitable composed layer to interface between the bi-layered flexible electrode 200 and the partially fabricated flexible perovskite solar device 420.

Following compression, the release substrate 410 (flexible polymer 410A with non-stick coating 411) is removed, for example, peeled off, from the top of the barrier film 415 (FIG. 7G), exposing the conductive film for electrical connection and resulting in the final flexible perovskite solar device 405.

As described above for the first embodiment illustrated in FIGS. 1 to 4, it should be appreciated that each of the described and illustrated the release substrates 210, 310 and 410 could equally include an activatable adhesive which can be activated, for example by heat or radiation to separate the transferrable electrode from the release substrate; or a low-cohesion sacrificial layer interposed between the flexible release substrate and the transferrable electrode, wherein the low-cohesion sacrificial layer has intrinsically low cohesion or has low cohesion when activated such that the flexible release substrate is separable from the transferrable electrode by breaking the low-cohesion sacrificial layer as described above. It should be appreciated that the use of these types of release layers equally results in the transferable electrode 100 being transferred onto and interfacing/adhering to the electronic carrier substrate 220, 320 and 420 using compression, and can be removed using the appropriate removal technique applicable to that release substrate configuration.

### EXAMPLES

### Example 1—Thin Film Perovskite Photovoltaic Electrode Materials

The conductive Ag paste for the printed electrodes was purchased from DuPont (PV416 conductor paste). The paste usually consists of Ag particles, binder material and a solvent. Propylene glycol methyl ether acetate (PGMEA) was used as the paste thinner material. The thermoplastic carbon paste was a commercial carbon paste purchased from Dycotec Materials, United Kingdom (DM-CAP-4701S).

The electron transport layer (ETL), aqueous-based SnO₂ nanoparticle dispersion, was synthesised by a microwave-assisted synthesis route using a precursor of tin (IV) chloride pentahydrate (SnCl₄·5H₂O, 98%, Alfa Aesar Co.) in a mixture of EtOH/H₂O (50% v/v). Biotage Initiator Classic microwave reactor (400 W) was used to synthesise the nanoparticles and the reaction was carried out at 100° C. for 30 min. The solid loading of the SnO₂ dispersion is approximately 4 wt %. The hole transport layer (HTL) solution was prepared with 72.66 mg of 2,2′,7,7′-tetrakis-(N,N-di-4-methoxyphenylamino)-9,9′-spirobifluorene (Spiro-OMeTAD, Luminescence Technologies Corp.) in 1 mL of chlorobenzene (Sigma-Aldrich), and adding 18 μL lithium bis(trifluoromethanesulfonyl)imide (LiTFSi, Sigma-Aldrich) stock solution (520 mg LiTFSI in 1 mL acetonitrile), 30 μL of 4-tert-Butylpyridine (TBP, Sigma-Aldrich), and 29 μL Tris(2-(1H-pyrazol-1-yl)-4-tert-butylpyridine)-cobalt (III) tris(bis(trifluoromethylsulfonyl) imide)) (FK209, Luminescence Technologies Corp.) stock solution (300 mg FK209 in 1 ml acetonitrile). The one-step perovskite solution with a Cs0.05FA0.81MA0.14Pb(I0.83Br0.17)₃ composition was prepared by dissolving lead iodide (PbI2, Tokyo Chemical Industry), formamidinium iodide (CH(NH2)2I, FAI, Greatcell Solar), methylammonium bromide (MABr, Greatcell Solar) and lead bromide (PbBr, Alfa Aesar) in 31 mL anhydrous DMF and DMSO (4:1 v/v) to achieve a final solution concentration of 1.4 M. 34 μL of caesium iodide (CsI, Sigma-Aldrich) (1.5 M) in DMSO was added to the precursor solution and left to stir at 65° C. for 60 min in a nitrogen-filled glovebox.

### Methodology

Flexible, printed electrodes illustrated and described in relation to FIGS. 1, 4(A) and 4(B) were fabricated directly onto a flexible release substrate, comprising a PET polymer sheet 110. The release mechanism of the film is via a non-stick thin-film silicone coating on one side of the polymer sheet 110 which results in very low adhesive properties. The release substrate was initially fixed to a flat platform before uniformly coating the surface with an Ag paste (PV416 conductor paste, Dupont) using doctor blading.

Once coated, the release substrate is transferred to a hot plate to anneal the Ag film at 135° C. for 2 minutes. Following this annealing stage, the film was transferred back to the platform and a uniform layer of carbon paste (Dycotec (DM-CAP-4701S),) was deposited on top of the thin Ag film via the same doctor blade method.

A second hot-plate annealing stage for 5 minutes at 135° C. was applied. The annealing stages of both the Ag and Carbon paste are important to evaporate any existing solvents that may otherwise ingress into the active layers of the solar devices and result in rapid device degradation.

The thermal treatment of the Ag-based and carbon-based coatings prior to contacting the R2R-fabricated PSC precursor stack was important for avoiding potential solvent diffusion into other functional layers of the device, which can lead to rapid device degradation.

The resulting multi-layered flexible electrode was then pressed onto a partially formed perovskite photovoltaic device (a flexible PSC precursor stacks—described below)—having the configuration illustrated in FIG. 5B by feeding both films between the rollers 132 of a calendar press 130. In this process, the carbon film bonds to the upper CTL layer 270 of the photovoltaic device 220. The non-stick release substrate 110 is then removed to expose the top Ag thin-film electrode.

The flexible PSC precursor stacks were prepared separately to the Ag/carbon electrodes by sequential deposition of the respective functional layers using readily scalable R2R coating techniques, namely slot-die coating and reverse-gravure coating. Whilst the perovskite layer and the 2,2′,7,7′-tetrakis-(N,N-di-4-methoxyphenylamino)-9,9′-spirobifluorene (Spiro-OMeTAD) HTL were deposited via slot-die coating, the SnO₂ ETL was deposited using reverse-gravure coating as we were able to achieve better solution wetting and a more uniform film.

The PSC device fabrication was undertaken completely in the ambient laboratory environment (17-21° C., 30-60% RH). R2R coating of the SnO₂ ETL, the perovskite layer and the Spiro-OMeTAD HTL was carried out on Mini-Labo™ or Mini-Labo Deluxe™ R2R coaters (Yasui Seiki Co. Ltd.). Firstly, the SnO₂ was coated on the TCE side of the PET/TCE substrate (OC50, Meko Print) using the reverse-gravure coating method (13 rpm roller speed, 0.2 m min-1 web speed, 11.5 mm coating width), followed by passing over an in-line hot plate at 135° C. for about 10 s. The PET/TCO/SnO₂ film then underwent R2R infra-red treatment for 8 min using an Orthotec R2R machine. The perovskite solution was then slot-die coated onto the SnO₂ film (12 μL min-1 flow rate, 0.3 m min-1 web speed, 13 mm coating width). The film was immediately passed over a hot-plate at 135° C. for about 5 s. The PET/TCE/SnO₂/Perovskite film was then rewound and the Spiro-OMeTAD solution was deposited via slot-die coating (15 μL min-1 flow rate, 0.3 m min-1 line speed, 6 mm coating width). For the flexible PSCs with printed electrodes, the PET/TCE/SnO₂/Perovskite/Spiro-OMeTAD film (PSC precursor stack) was cut into 10-cm long sections and passed through a calendar press (Minder-Hightech MD-Jr100; 0.4 m min-1 feed rate) together with the printed Ag/carbon stack to complete the PSC device. The roller gap was measured by two electronic distance sensors (Yueqing instrument co.) and thickness gauge sticks (100B-17, Jinghua). For the flexible PSCs with evaporated electrodes, an 80-nm thick Au layer was deposited by thermal evaporation using a shadow mask to define an active device area of 0.2 cm²

The PSCs were fabricated with a conventional n-i-p architecture; PET/TCE/SnO₂/Cs0.05FA0.81MA0.14Pb(I0.83Br0.17)₃/Spiro-OMeTAD/carbon/Ag.

### Device Characterization

All device characterization was performed in an ambient laboratory atmosphere (17 to 21° C., 40 to 60% RH). Current density-voltage (J-V) measurements were undertaken using a class ABA solar simulator (Newport Oriel Sol2A, Xenon-lamp light source). The solar simulator was calibrated to 1-sun (1000 W m⁻²) AM 1.5G illumination using a certified reference cell (Enlitech with KG-2 filter, certified by Enlitech in accordance with IEC 60904-1:2006) and a source meter (Keithley 2400). A shadow mask was used to define a cell active area of 0.08 cm2. J-V measurements were carried out in the forward (increasing forward bias) and reverse (decreasing forward bias) scan directions over the voltage range −0.2 V-1.2 V at a 20 mV s⁻¹ scan rate. Light-beam induced current (LBIC) images were recorded using a commercial LBIC system from InfinityPV. External quantum efficiency (EQE) measurements were performed using an incident photon-to-current conversion efficiency (IPCE) measurement apparatus from Peccell Technologies, Inc (PEC-S20). The operational stability was characterized via maximum power point (MPP) tracking using a source meter (Keithley 2400) under continuous illumination with an LED solar simulator light source (Candlelight systems), calibrated to 1-sun-intensity illumination using the reference cell mentioned prior. The mechanical stability of the devices was characterized by using an in-house bending machine. Four-point-probe measurements were taken in the ambient laboratory atmosphere using a Jandel four-point-probe instrument and Jandel RM3000 test unit.

### Discussion

Good interface contact between the carbon film of the printed electrode and the HTL must be established for optimal PSC efficiency. In this work, good contact was achieved by passing the PSC precursor stack together with the printed Ag/carbon stack through a calendar press, as illustrated in FIG. 1. The applied pressure was adjusted by varying the distance between the two rollers of the calendar press, monitored using two electronic sensors having an accuracy of 10 μm and thickness gauge sticks. The compression, P_{comp}, was calculated as a percentage by measuring the total thickness of the PSC precursor stack plus the printed electrode stack before lamination, h₁, and the distance between the two rollers of the calendar press, h₂, according to Equation (1).

$${P}_{comp} = ( ( {h}_{1} - {h}_{2} ) / {h}_{1} ) \times 100 \% \qquad ( 1 )$$

The performance of PSC devices was monitored as a function of P_{comp} between 12% and 60%. A compression of 12% was found to be the lowest value needed to achieve adequate adhesion between the printed carbon layer and the HTL of the PSC precursor stack with the 17% and 20% variants giving the best-performing devices.

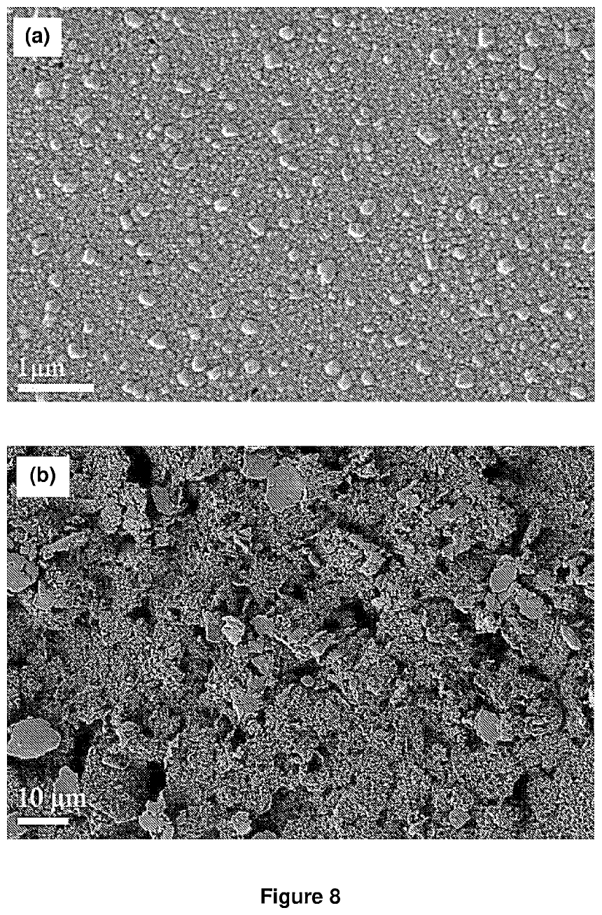

The bilayered electrode thickness was also optimized to facilitate efficient charge transfer and permit a high degree of flexibility. As shown in FIG. 8(a), the Ag film is comprised of tightly packed Ag particles which aids the charge collection and lateral charge transport to the electrical contacts. An optimized Ag film thickness of approximately 20 μm was found to exhibits high conductivity (around 50 mΩ⁻¹) and good mechanical flexibility to withstand repeated bending stresses.

Furthermore, the macroporous carbon film (FIG. 8b) was found to be important to establishing strong interface contact with the receiving PSC precursor stack. Without this carbon interlayer, the printed Ag electrodes were found to easily delaminate from the PSC precursor stack. The carbon film thickness influences both its flexibility and its conductivity.

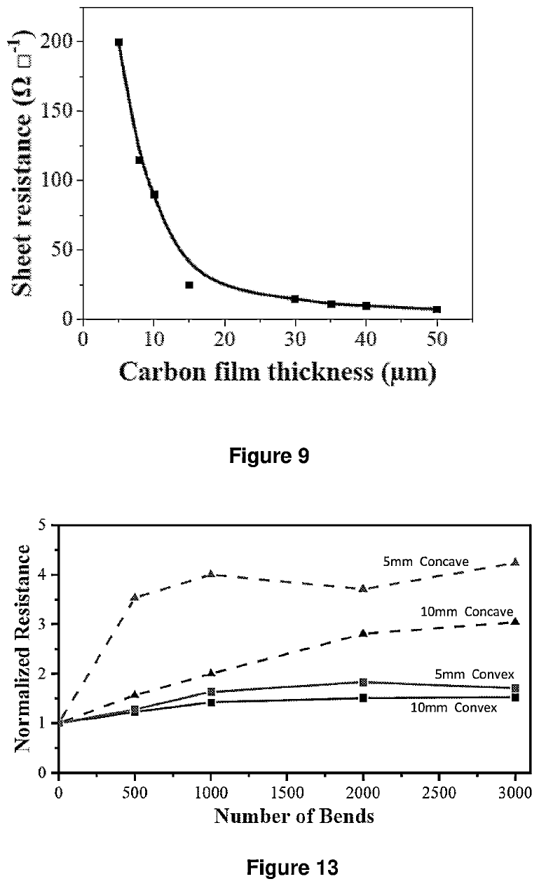

The sheet resistance for various carbon film thicknesses as illustrated in FIG. 9 demonstrates an inverse relationship between film thickness and conductivity. It was also found that carbon thicknesses below 15 μm resulted in an exponential increase in sheet resistance. Conversely, it was found that when the carbon films were too thick (around 70 μm), the film would often crack or snap upon bending, thus being unsuitable for this application. Therefore, the carbon film thickness was optimized to balance the two critical performance factors: conductivity, and flexibility. Carbon dry-film thicknesses (before transfer to the PSC precursor stack) were varied from 5 to 70 μm and it was found that poor interfacial contact was observed when the carbon layer was too thin (≤5 μm), resulting in reduced charge carrier collection and thus lower PSC device performance. For carbon film thicknesses of 10 to 50 μm, there were marginal differences in the PSC device performance and all electrodes exhibited excellent electrode adhesion to the PSC precursor stack. For carbon films of approximately 70 μm thickness, whilst some devices still exhibited high performance, the thick bilayered electrodes were significantly more fragile and prone to cracking and delamination during transfer to the PSC precursor stack. Balancing the factors of flexibility and conductivity, an optimized carbon film thickness of 30 to 40 μm was adopted.

### Performance of Optimized PSCs

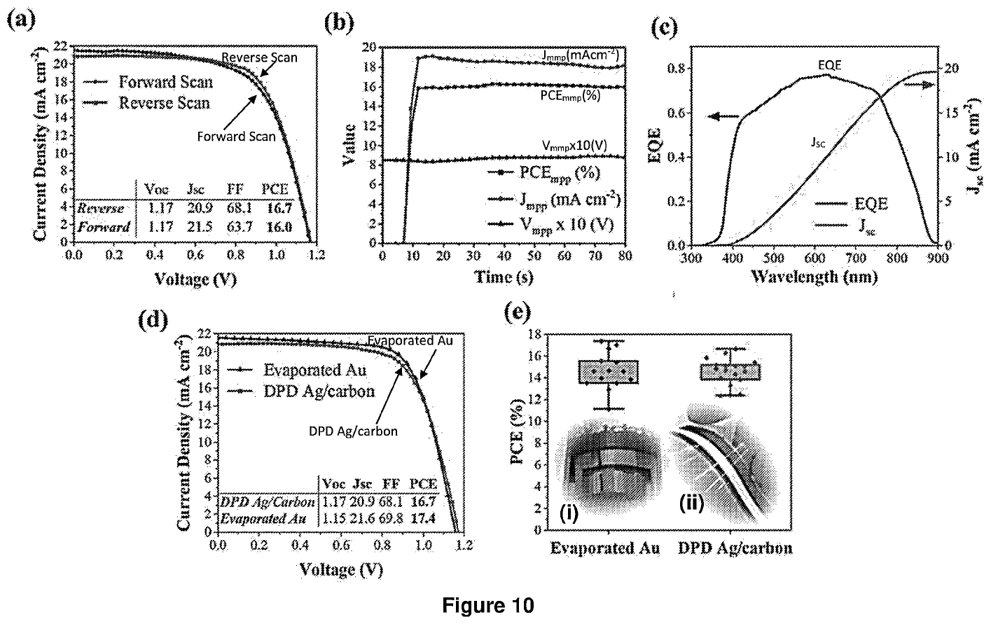

The J-V curves in forward and reverse scan directions, along with the PV parameters for the champion flexible, fully printed, and R2R-fabricated PSC are presented in FIG. 10a. A shadow mask was used to define an active cell area of 0.08 cm². The champion device displayed a PCE of 16.7% (Voc=1.17 V, Jsc=20.9 mA cm², FF=68.1%) in a reverse scan direction. The inventors consider that this result represents the highest recorded efficiency to date for a flexible, R2R-fabricated PSC produced by vacuum-free deposition of all functional layers, apart from the TCE. The forward direction J-V scan indicates minimal hysteresis, with a PCE of 16.0% (Voc=1.17 V, Jsc=21.5 mA cm², FF=63.7%). Maximum power point (MPP) tracking of the champion PSC with printed DPD Ag/carbon electrode (FIG. 10b) indicates a stabilized PCE of 16.0% for over 80 s under continuous 1-sun illumination. Furthermore, the external quantum efficiency (EQE) and cumulative Jsc (FIG. 10c) indicate broad light absorption in the visible wavelength range and validate the Jsc of approximately 20 mA cm⁻².

Flexible devices having an evaporated Au electrode were also fabricated from the same batch of PSC precursor stacks, as controls. A comparison between the J-V curves and PV parameters of the champion PSC with an evaporated Au-electrode and that with the printed DPD electrode is shown in FIG. 10d. The best Au-electrode device displayed a PCE of 17.4% (Voc=1.15 V, Jsc=21.6 mA cm⁻², and FF=69.8%) in the reverse scan, only marginally higher than the champion PSC with the printed DPD electrode, and marking a record PCE for a flexible R2R coated PSC with an evaporated Au electrode. The reproducibility of the DPD fabrication method developed in this work, compared to the Au-electrode devices, is demonstrated in the box plot in FIG. 10e. The PSCs with printed DPD electrodes exhibited outstanding reproducibility and were only out-performed by a couple of the evaporated Au electrode PSCs. This marginally lower performance is attributed, at least in part, to the lack of reflection of residual transmitted incident light from the printed Ag/carbon electrode back into the perovskite layer, compared to the highly reflective Au electrode.

### Operational and Mechanical Stability

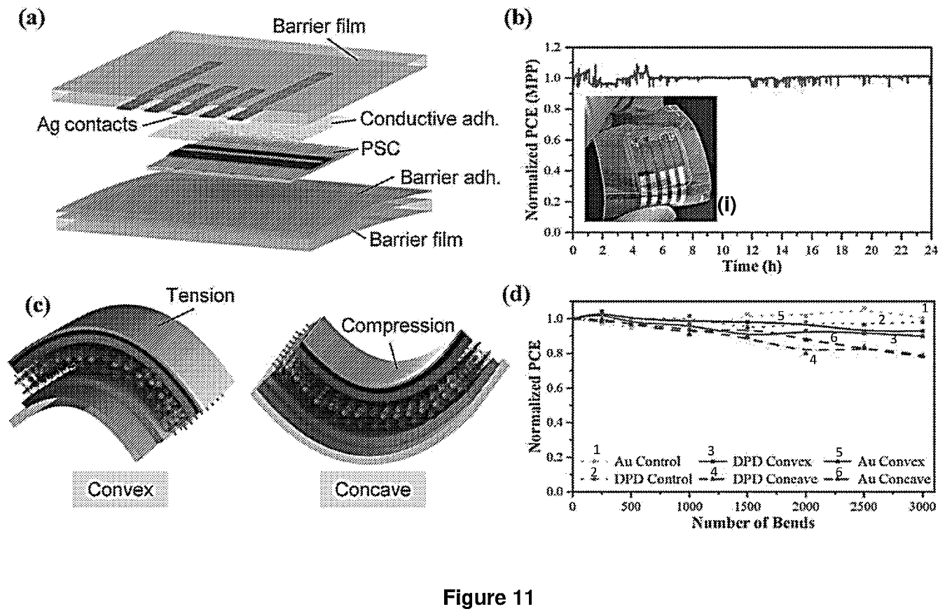

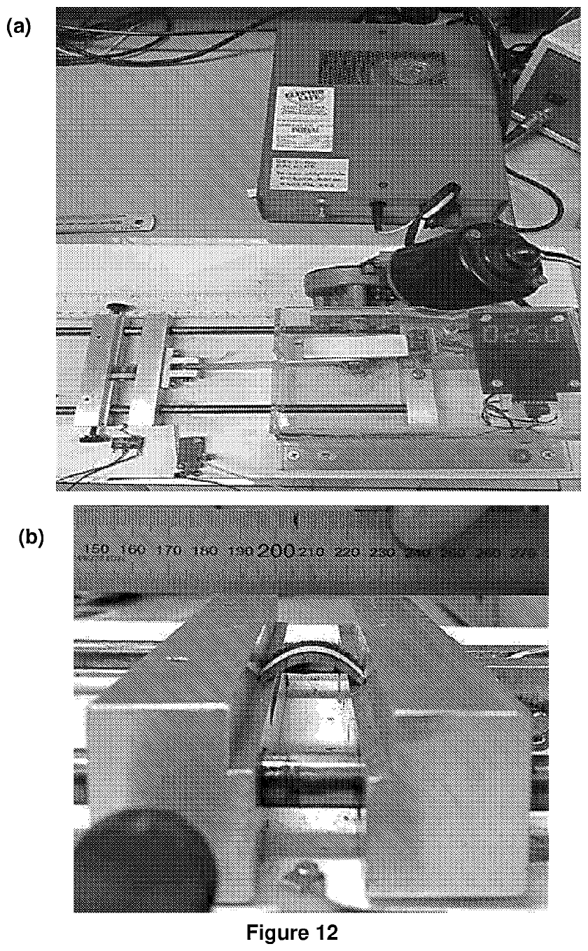

The operational stability of the flexible R2R-fabricated PSCs produced in this work was investigated under MPP conditions at 1-sun illumination in an ambient laboratory environment. The PSCs were encapsulated within flexible polymeric barrier materials to protect them from degradation due to ambient moisture and oxygen. The PSCs and barrier materials were all appropriately preconditioned prior to encapsulation to mitigate the risk of moisture and oxygen outgassing. The encapsulation architecture is illustrated in FIG. 11a. A 200 nm thick Ag pattern was evaporated onto the back-barrier film to enable electrical contact with the device. Electrically conductive adhesive tape (conductive adh.) was used to improve the electrical connection between the printed Ag/carbon electrode, and the evaporated Ag pattern. A photo of the fully encapsulated PSC device is shown in the inset in FIG. 11b. As shown in FIG. 11b, PSCs exhibited negligible loss of PCE after 24 h of MPP tracking under continuous 1-sun intensity illumination in an ambient laboratory atmosphere (21° C., 40-60% RH). The slight variation seen in the PCE is due to a sporadic flickering of the illumination lamp throughout the test period. Cyclic-bending fatigue testing was conducted to evaluate the mechanical robustness of the R2R-fabricated PSC devices and to compare the printed DPD electrode with control PSCs having an evaporated Au electrode. The bending test was performed on unencapsulated devices in an ambient laboratory environment using an in-house constructed bending apparatus (FIG. 12). The devices were subjected to convex and concave bending with a bending radius of 10 mm. These bending regimes applied tensile (convex) or compressive (concave) stress to the electrode, and one cycle represents the sequence: flat→bend-≥flat.

A reference device was used to assess the stability of devices when stored in the ambient environment for the duration of the bending test, as indicated by the grey lines in FIG. 11d. After 3000 bending cycles, there were no visible signs of damage or delamination of the printed electrodes, indicating good adhesion between the carbon and Spiro-OMeTAD layers. As seen in FIG. 11d, the PSC device with printed DPD electrode exhibited outstanding mechanical robustness, retaining over 90% of its initial PCE after 3000 convex bends in the ambient laboratory environment. This is directly comparable to the Au-electrode PSC which retained about 93% of its initial PCE after the same number of convex bends.

Slightly more degradation was observed when the devices were subjected to concave bending. The PSCs with printed DPD or evaporated-Au electrodes exhibited almost identical performance after 3000 concave bending cycles, retaining just under 80% of their initial PCE. To further investigate the cause of this degradation, resistance of the printed DPD electrode was measured using a four-point probe (FIG. 13). Concave bending was found to be more damaging to the electrode and resulted in an increase in sheet resistance, particularly under extreme bending (5 mm radius). Whilst there is only a slight increase in sheet resistance between the 10 mm radius and 5 mm radius for convex bending, an increase of more than 350% is observed when the electrode is subjected to only 500 concave bending cycles with a 5 mm radius. This increase in resistance with concave bending is assumed to contribute to the observed decrease in PCE seen in the mechanical fatigue tests. Despite this, not only did the PSCs with printed DPD electrodes exhibit comparable mechanical robustness to the PSCs with evaporated Au electrodes, there were also no signs of delamination or film damage for the printed devices even under the harsh 5 mm radius bending regime.

### Example 2—Testing of Different Materials/Inks

The method as set out in Example 1 was conducted using different carbon paste compositions, as listed in table 1. All tested carbon pastes exhibited good lamination adhesion.

TABLE 1
Different Carbon pastes used in transferrable electrode test devices.

| Carbon paste | Source | Lamination |
|---|---|---|
| Dycotec DM-CAP-4701-S | Dycotec* | YES |
| Dycotec DM-CAP-4311-S | Dycotec* | YES |
| Jelcon CH-8 | JUJO Chemical** | YES |

*Dycotec Materials Ltd, United Kingdom
**JUJO Chemical Co Ltd, Japan

### Example 3—Trial of Different Charge Transport Materials

The method as set out in Example 1 was conducted using different charge transport material compositions, as listed in table 2.

Table 2 indicates that a range of organic charge transport materials can also be used with all the tested materials working perfectly in terms of lamination and adhesion. Poor lamination and some delamination was only observed when no charge transport material was used in the device layup and the metallic Ag-based and carbon film bi-layered electrode taught in Example 1 was pressed just onto the perovskite layer instead.

The different materials were produced as follows:
Spiro-OMeTAD with additives: The following solution was prepared and coated onto the perovskite photoactive layer: 72.66 mg of 2,2′,7,7′-tetrakis-(N,N-di-4-methoxyphenylamino)-9,9′-spirobifluorene (Spiro-OMeTAD, Luminescence Technologies Corp.) in 1 mL of chlorobenzene (Sigma-Aldrich), before adding 18 μL lithium bis(trifluoromethanesulfonyl)imide (LiTFSi, Sigma-Aldrich) stock solution (520 mg LiTFSI in 1 mL acetonitrile), 30 μL of 4-tert-Butylpyridine (TBP, Sigma-Aldrich), and 29 μL Tris(2-(1H-pyrazol-1-yl)-4-tert-butylpyridine)-cobalt (III) tris(bis(trifluoromethylsulfonyl) imide)) (FK209, Luminescence Technologies Corp.) stock solution (300 mg FK209 in 1 mL acetonitrile).
Spiro-OMeTAD without additives: The following solution was prepared and coated onto the perovskite photoactive layer: 72.66 mg of 2,2′,7,7′-tetrakis-(N,N-di-4-methoxyphenylamino)-9,9′-spirobifluorene (Spiro-OMeTAD, Luminescence Technologies Corp.) in 1 mL of chlorobenzene (Sigma-Aldrich)
PPDT2FBT with additives: The following solution was prepared and coated onto the perovskite photoactive layer: 10 mg of poly[(2,5-bis(2-hexyldecyloxy)phenylene)-alt-(5,6-difluoro-4,7-di(thiophen-2-yl)benzo[c][1,2,5]-thiadiazole)] (PPDT2FBT, 1-Material Incorporated) was dissolved in 1 mL of chlorobenzene before adding 18 μL lithium bis(trifluoromethanesulfonyl)imide (LiTFSi, Sigma-Aldrich) stock solution (520 mg LiTFSI in 1 mL acetonitrile), 30 μL of 4-tert-Butylpyridine (TBP, Sigma-Aldrich), and 29 μL Tris(2-(1H-pyrazol-1-yl)-4-tert-butylpyridine)-cobalt (III) tris(bis(trifluoromethylsulfonyl) imide)) (FK209, Luminescence Technologies Corp.) stock solution (300 mg FK209 in 1 mL acetonitrile).
PPDT2FBT without additives: The following solution was prepared and coated onto the perovskite photoactive layer: 10 mg of poly[(2,5-bis(2-hexyldecyloxy)phenylene)-alt-(5,6-difluoro-4,7-di(thiophen-2-yl)benzo[c][1,2,5]-thiadiazole)] (PPDT2FBT, 1-Material Incorporated) was dissolved in 1 mL of chlorobenzene.
Organic Photovoltaic (OPV) active layer comprised of a PC61BM (Ossila) and P3HT (Merck) bulk heterojunction blend.
PCBM/PEIE: The following solutions were prepared and coated onto the perovskite photoactive layer: 12 mg/ml of phenyl-C61-butyric acid methyl ester (PC61BM, Ossila) was dissolved in chlorobenzene (Sigma-Aldrich) and filtered through a 0.22 μL polytetrafluoroethylene (PTFE) filter. 3 μL mL-1 of polyethylenimine ethoxylated (PEIE, Sigma-Aldrich) was diluted in anhydrous isopropanol (IPA, Sigma-Aldrich) and stirred at room temperature for 1 hour.

TABLE 2
Different charge transport materials used
in transferrable electrode test devices.

| Top charge transport material | Lamination |
|---|---|
| Spiro-OMeTAD with additives | YES |
| Spiro-OMeTAD without additives | YES |
| PPDT2FBT with additives | YES |
| PPDT2FBT without additives | YES |
| Organic Photovoltaic (OPV) active layer | YES |
| PCBM/PEIE | YES |
| No HTL (just laminate onto perovskite) | No |

### Example 4—Transferring Carbon Film Electrode

The method as set out in Example 1 was conducted, but with only a uniform layer of carbon paste (Commercial carbon paste Dycotec 4701s, Dycotec Materials Ltd, United Kingdom) deposited on top of the non-stick thin-film coating of the release substrate using a doctor blade method. That carbon paste is then annealed as set out in Example 1.

The trials found that a transferable electrode with a carbon-based electrode layer had good adhesion and lamination when pressed onto a partially formed perovskite photovoltaic device as set out in Example 1. However, the final photovoltaic device performance was significantly lower than the device with the conductive Ag paste produced in Example 1. It was thought that this difference was a result of Ag paste providing an important role in providing high conductivity for the lateral flow of charges to the electrical contacts.

### Example 5—Transferring Ag Film Electrode

The method as set out in Example 1 was conducted, but with only a uniform layer of Ag paste (Commercial Ag paste (PV416, Dupont)) deposited on top of the non-stick thin-film coating of the release substrate using a doctor blade method. That Ag paste is then annealed as set out in Example 1. Carbon paste was not coated on top of the Ag conductive layer.

Removing the carbonaceous film simplifies the electrode architecture to just have a single-layered metallic-based electrode. The trials found that a transferable electrode with an Ag-based electrode layer had good adhesion and lamination when pressed onto a partially formed perovskite photovoltaic device as set out in Example 1.

However, whilst a number of devices functioned, a number of the devices that were formed exhibited short-circuiting. It was thought that this was due to the hard Ag particles penetrating through the soft device layers during lamination, short-circuiting the device. Hence the inclusion of a carbonaceous/organic conductor layer can function as a buffer between the Ag electrode layer and the upper layer of the partially formed perovskite photovoltaic device to prevent the penetration of these particles. This macroporous carbon layer thus plays an important role in forming an interlayer between the PSC precursor stack and the conductive printed Ag layer.

### Example 6—Transferable Electrode with a Sacrificial Layer

A coating composition for preparing a sacrificial layer was prepared by mixing 10 ml of commercial aqueous 1.3-1.7% PEDOT:PSS solution (Clevios Al 4083, Heraeus), 200 mg of polyethylene oxide (PEO), a water-soluble low-melting point polymer (molecular weight 100 000 Daltons, melting point 65° C.), and 10 ml of 2-propanol. A sacrificial layer was produced by applying this mixture by roll-to-roll slot die coating onto a roll of uncoated polyethylene terephthalate (PET) film. The mixture was deposited in a 25 mm wide continuous strip at a loading of 1 μl/cm² (wet film thickness thus about 10 microns) of the solution at room temperature and then dried at 130° C. for 30 sec. The dried film, which was non-tacky at room temperature, became soft and tacky when heated above 80° C. In a Scotch tape test, the tape was firmly adhered at room temperature but peeled off easily when heated to 80° C. Based on visual inspection, the sacrificial layer remained present on the PET film following detachment.

A transparent conductive layer was then produced by applying a commercial aqueous 1% PEDOT:PSS solution (S315, Agfa) by roll-to-roll slot die coating onto the sacrificial layer. The PEDOT:PSS solution was deposited in a 13 mm wide continuous strip at a loading of 3.8 μl/cm² (wet film thickness thus about 38 microns) at 0.3 m/min speed and dried at 130° C. for 30 sec. The sheet resistance of the transparent conductive layer was about 80 ohm/sq. This produced the transferrable electrode.

The resulting multi-layered flexible electrode was therefore configurable to be pressed onto a partially formed perovskite photovoltaic device—having the configuration illustrated in FIG. 6B by feeding both films between the rollers 132 of a calendar press 130.

The separability of the transferrable electrode and the resulting multi-layered photovoltaic device, from the release substrate was investigated by a Scotch tape test at 80° C. The device detached readily from the PET substrate via breakage of the heat-activated sacrificial layer. The sheet resistance of the transparent conductive layer, as exposed after removal of the PET film, was about 90 to 100 ohm/sq.

PEDOT:PSS was included in the sacrificial layer for several reasons. Firstly, it overcame the problem of dewetting encountered when roll-to-roll slot die coating a solution of PEO only. Secondly, the inclusion of the conductive PEDOT:PSS is believed to mitigate the effects of sacrificial layer residue on the conductivity of the transparent conductive layer.

Those skilled in the art will appreciate that the invention described herein is susceptible to variations and modifications other than those specifically described. It is understood that the invention includes all such variations and modifications which fall within the spirit and scope of the present invention.

Where the terms “comprise”, “comprises”, “comprised” or “comprising” are used in this specification (including the claims) they are to be interpreted as specifying the presence of the stated features, integers, steps or components, but not precluding the presence of one or more other feature, integer, step, component or group thereof.

1.-63. (canceled)

64. A transferrable electrode arrangement comprising:
a flexible release substrate that includes a release surface; and
a transferrable electrode comprising at least one conductive layer located over the interfacing conductive layer of the release substrate comprising a solution-processed conductive layer,
wherein the at least one conductive layer includes an interfacing conductive layer that interfaces with a receiving surface, and comprises a carbonaceous conductive layer or an organic conductive layer;
and wherein the transferrable electrode is releasably attached to the release surface of the release substrate.

65. The transferrable electrode arrangement according to claim 64, wherein the at least one conductive layer comprises at least one further conductive layer selected from: a metallic-based conductive layer; a carbonaceous conductive layer; an organic conductive layer; or a combination thereof.

66. The transferrable electrode arrangement according to claim 64, wherein the at least one organic conductive layer comprises a charge transport layer, preferably a PEDOT-based conductive layer; and/or the carbonaceous conductive layer is formed from a carbon-based paste comprising a conductive carbonaceous filler, a binder material and an organic solvent.

67. The transferrable electrode arrangement according to claim 64, wherein the transferrable electrode further comprises at least one barrier film layer located between the release substrate and the at least one conductive layer; and/or the at least one metallic-based conductive layer comprises an Ag, Al, Cu or Au-based layer; and/or the release substrate comprises a flexible polymer, preferably a polymer film, more preferably a polyethylene terephthalate (PET), a polyethylene naphthalate (PEN), a polypropylene (PP), or a ethylene tetrafluoroethylene (ETFE) film, a paper film or an aluminium foil.

68. The transferrable electrode arrangement according to claim 64, wherein
the release surface comprises a non-stick surface, preferably a non-stick coating or a low adhesion coating, and more preferably is selected from the group consisting of a fluorinated polymer and a silicone polymer, preferably polytetrafluoroethylene (PTFE), or silicone derivatives such as siloxane; or
the release surface comprises an activatable adhesive which can be activated to separate the transferrable electrode from the release substrate and which preferably comprises a heat-activatable adhesive polymer, preferably comprising a thermoplastic polymer selected from the group consisting of an ethylene-vinyl acetate (EVA) copolymer, a polyethylene, a polyethyleneoxide (PEO) and a polystyrene (PS); or
a low-cohesion sacrificial layer is interposed between the flexible release substrate and the transferrable electrode, wherein the low-cohesion sacrificial layer has intrinsically low cohesion or has low cohesion when activated such that the flexible release substrate is separable from the transferrable electrode by breaking the low-cohesion sacrificial layer preferably comprising at least one of:
a low-cohesion organic non-polymeric solid; or
an activatable adhesive which can be activated by heat or radiation to breaking the low-cohesion sacrificial layer and thereby separate the transferrable electrode from the release substrate.

69. The transferrable electrode arrangement according to claim 64, wherein the at least one conductive layer has a dry layer thickness from 1 μm to 100 μm, preferably from 10 to 80 μm, more preferably from 20 to 60 μm, and yet more preferably about 40 μm.

70. An optoelectronic device comprising:
a flexible substrate coated with a transparent conductive oxide coating;
a first charge transport layer located over the flexible substrate, such as a hole transporting layer, or an electron transport layer;
at least one photoactive layer located over the first charge transport layer; and
the transferrable electrode arrangement according to claim 64 located over the photoactive layer, with the interfacing conductive layer located over the photoactive layer.

71. The optoelectronic device according to claim 70, further comprising a second charge transport layer, such as a hole transporting layer, or an electron transport layer, located over the flexible substrate located between the at least one photoactive layer and the transferrable electrode.

72. The optoelectronic device according to claim 70, wherein at least one of the first charge transport layer, or the second charge transport layer is preferably selected from at least one of: tin oxide, PEDOT, PEDOT:PSS, SpiroOMeTAD, PPDT2FBT, or Phenyl-C61-butyric acid methyl ester (PCBM)/polyethylenimine ethoxylated (PEIE).

73. The optoelectronic device according to claim 70, wherein the photoactive layer comprises at least one perovskite layer or at least one organic photovoltaic cell active layer; and/or the transparent conductive oxide (TCO) coating is selected from at least one of tin-doped indium oxide (ITO), fluoridedoped tin oxide (FTO), doped zinc oxides such as aluminium doped zinc oxide (AZO), or indium doped cadmium-oxide; and/or
the flexible substrate comprises a polymer, preferably a polymer film, preferably a polyethylene terephthalate (PET), a polyethylene naphthalate (PEN), or a ethylene tetrafluoroethylene (ETFE) film, and more preferably a polyethylene terephthalate (PET) film; and/or
the release substrate is at least partially separated from covering the transferrable electrode.

74. A method of forming a transferrable electrode for a flexible electronic device, comprising:
providing a flexible release substrate that includes a release surface;
applying at least one layer of a conductive medium over the release surface of the release substrate, the conductive medium comprising a flowable mixture of a solvent with a conductive composition, the at least one layer of a conductive medium including an interfacing conductive composition that is configured to form an interfacing conductive layer to interface with a receiving surface, the interfacing conductive composition comprising a flowable mixture of a solvent with one of: a carbonaceous conductive composition, or an organic conductive composition; and
heat treating the at least one layer of a conductive medium to remove said solvent from each layer of the conductive medium,
thereby forming a transferrable electrode on said release substrate,
wherein the transferrable electrode is releasably attached to the release surface of the release substrate.

75. The method according to claim 74, wherein the at least one layer of a conductive medium further comprises at least one further layer comprising a flowable mixture of a solvent with at least one of: a metallic-based composition, a carbonaceous conductive composition, or an organic conductive composition.

76. The method according to claim 74, wherein the transferrable electrode comprises at least two layers of conductive medium, and the applying step comprises:
applying at least one layer of a metallic-based conductive medium comprising a flowable mixture of a solvent with the metallic-based composition onto the release substrate to form a first conductive layer; and
applying at least one layer of the interfacing conductive composition onto the first conductive layer to form an interfacing conductive layer.

77. The method according to claim 74, wherein the heat-treating step comprises heat treatment of the transferrable electrode after applying each conductive medium layer thereon.

78. The method according to claim 76, wherein the at least one layer of metallic-based conductive medium is heat-treated prior to application of the interfacing conductive composition thereon; and/or the interfacing conductive composition is heat-treated after application on the first conductive layer.

79. The method according to claim 74, further comprising:
applying at least one barrier film material composition between the release substrate and the at least one layer of a conductive medium to form at least one barrier film layer; and wherein the at least one layer of a conductive medium is printed onto the at least one barrier film layer.

80. The method according to claim 75, wherein the at least one layer of a metallic-based conductive medium comprises a metallic based paste, preferably an Ag, Cu, Al or Au containing paste; and/or
the at least one layer of organic conductive composition comprises a charge transport layer composition, preferably a PEDOT-based conductive layer composition; and/or
the at least one layer of carbonaceous conductive composition is formed from a carbon-based paste comprising a conductive carbonaceous filler, a binder material and an organic solvent;
and/or the release substrate comprises a flexible polymer, preferably a polymer film, more preferably a polyethylene terephthalate (PET), a polyethylene naphthalate (PEN), a polypropylene (PP), or an ethylene tetrafluoroethylene (ETFE) film, a paper film, or an aluminium foil.

81. The method according to claim 74, wherein the transferrable electrode has a dry layer thickness from 1 μm to 100 μm, preferably from 10 to 80 μm, more preferably from 20 to 60 μm, and yet more preferably about 40 μm.

82. The method according to claim 74, wherein the release surface comprises an activatable adhesive which can be activated to separate the transferrable electrode from the release substrate; such as a heat-activatable adhesive polymer, preferably comprising a thermoplastic polymer selected from the group consisting of an ethylene-vinyl acetate (EVA) copolymer, a polyethylene, a polyethyleneoxide (PEO) and a polystyrene (PS); or
the release surface comprises a low-cohesion sacrificial layer interposed between the flexible release substrate and the transferrable electrode, wherein the low-cohesion sacrificial layer has intrinsically low cohesion or has low cohesion when activated such that the flexible release substrate is separable from the transferrable electrode by breaking the low-cohesion sacrificial layer.

83. The method according to claim 74, wherein each layer of conductive medium is applied onto the release substrate using at least one of: casting, doctor blading, blade coating, bar coating, screen printing, inkjet printing, pad printing, knife coating, meniscus coating, slot die coating, gravure printing, reverse gravure printing, kiss coating, micro-roll coating, curtain coating, slide coating, spray coating, flexographic printing, offset printing, rotatory screen printing, or dip coating.

84. The method according to claim 74, further including at least one pre-treatment step to the transferrable electrode prior to applying the transferrable electrode onto the surface of the electronic carrier substrate selected from at least one of:
pre-pressing of the electrode to improve the inter-particular connectivity of the electrode as well the connectivity between the layers of conductive medium;
heat treating at elevated temperatures for prolonged time; or
at least one solvent exchange treatment.

85. A method of forming a flexible electronic device, comprising:
A. providing a transferrable electrode arrangement in accordance with claim 64;
B. providing an electronic carrier substrate having selected underlying electronic layers configured for receipt of the transferrable electrode on a receiving surface thereon;
C. applying the transferrable electrode onto the receiving surface of the electronic carrier substrate; and
D. removing the release substrate from the transferrable electrode,
thereby producing an electronic device with the transferrable electrode applied thereon.

86. The method according to claim 85, wherein the transferrable electrode is pressed and/or compressed onto the receiving surface of the electronic carrier substrate; and/or the electronic carrier substrate comprises:
a flexible substrate coated with a transparent conductive oxide coating;
a first charge transport layer located over the flexible substrate;
at least one photoactive layer located over the first charge transport layer;
and the receiving surface comprises the photoactive layer; or the electronic carrier substrate comprises:
a flexible substrate coated with a transparent conductive oxide coating;
a first charge transport layer located over the flexible substrate;
a first charge transport layer located over the flexible substrate;
a second charge transport layer located over the at least one photoactive layer, and the receiving surface comprises the second charge transport layer.

87. The method according to claim 85, wherein at least one of the first charge transport layer or the second charge transport layer comprises at least one hole transporting layer, at least one electron transport layer; or wherein at least one of the first charge transport layer or the second charge transport layer is preferably selected from at least one of: tin oxide, PEDOT, PEDOT:PSS, SpiroOMeTAD, PPDT2FBT, or Phenyl-C61-butyric acid methyl ester (PCBM)/polyethylenimine ethoxylated (PEIE)

88. The method according to claim 85, wherein the photoactive layer comprises at least one perovskite layer or at least one organic photovoltaic cell active layer; and/or wherein the transparent conductive oxide (TCO) coating is selected from at least one of tin-doped indium oxide (ITO), fluoride-doped tin oxide (FTO), doped zinc oxides such as aluminium doped zinc oxide (AZO), or indium doped cadmium-oxide; and/or
wherein the flexible substrate comprises a polymer, preferably a polymer film, preferably a polyethylene terephthalate (PET), a polyethylene naphthalate (PEN), or an ethylene tetrafluoroethylene (ETFE) film, and more preferably a polyethylene terephthalate (PET) film.

89. The method according to claim 85, wherein the electronic carrier substrate is prepared by:
providing a flexible substrate coated with a transparent conductive oxide coating;
applying a first charge transport layer located over the flexible substrate;
applying at least one photoactive layer located over the first charge transport layer; and
optionally applying a second charge transport layer located over the at least one photoactive layer,
wherein each layer is optionally applied over the subsequent layer using at least one of:
casting, doctor blading, blade coating, bar coating, screen printing, inkjet printing, pad printing, knife coating, meniscus coating, slot die coating, gravure printing, reverse gravure printing, kiss coating, micro-roll coating, curtain coating, slide coating, spray coating, flexographic printing, offset printing, rotatory screen printing, or dip coating.

90. The method according to claim 85, comprising a roll-to-roll printed electrode transfer method.
